(19) United States
(12) Patent Application Publication
(10) Pub. No.: US 2019/0259892 A1
(43) Pub. Date: Aug. 22, 2019

(54) Gravity-Oriented and Vertically-Oriented High-Power-Density Slatted Bifacial Agile Smart Power Generators

(71) Applicant: Sigmagen, Inc., Los Altos, CA (US)

(72) Inventor: Mehrdad Moslehl, Los Altos, CA (US)

(21) Appl. No.: 16/011,519

(22) Filed: Jun. 18, 2018

Related U.S. Application Data
(60) Provisional application No. 62/528,934, filed on Jul. 5, 2017.

(51) Int. Cl. H01L 31/046; H01L 31/05; H01L 31/0224; H01L 31/02

(52) U.S. Cl. CPC H01L 31/046; H01L 31/02008; H01L 31/022425; H01L 31/0504

(57) ABSTRACT

A vertically-deployable solar photovoltaic electricity generator comprising a plurality of bifacial photovoltaic power generating slats with longer and shorter peripheral slat boundary sides, and a plurality of power maximizing integrated circuits, is disclosed. The plurality of bifacial photovoltaic power generating slats are retractable for volume compaction mode and expandable with an expansion axis substantially parallel to the direction of gravity for photovoltaic electricity generation mode. The vertically-deployable solar photovoltaic electricity generator is photovoltaic electricity generation mode whenever expanded with the expansion direction parallel to the direction of gravity, and with the longer slat boundary substantially perpendicular the direction of gravity. The adjacent pairs of slats within the plurality of bifacial photovoltaic power generating slats are spaced apart by a finite gap allowing collection of the light on each of the bifacial photovoltaic power generating slats in the photovoltaic electricity generation mode.

### RELATED APPLICATIONS

This application claims priority to the U. S. Provisional Application No. 62/521,306 filed Jun. 16, 2017 and U.S. Provisional Application No. 62/528,934 filed Jul. 5, 2017, which are expressly incorporated herein by reference.

### BACKGROUND

The disclosure relates to solar photovoltaic (PV) electricity generation systems more specifically, it relates to portable, lightweight, high-power-density, and rapidly deployable and retractable solar PV electricity generation systems having a slatted module architecture capable of gravity-oriented and vertically-oriented smart power generation and methods of making the same.

### SUMMARY

Described herein are various structures and manufacturing methods for Rapidly Deployable & Portable Smart Power Generators (abbreviated as “RDP-SPG” and sometimes referred to as generator modules or generation modules) comprising a plurality of lightweight, modular and scalable electric power-generating building blocks, known as Smart Power Slat (SPS) units. Furthermore, also described is an architecture for ultra-lightweight RDP-SPG Modules with distributed tilt adjustment. Representative designs of RDP-SPG modules with varying dimensions, configurations, and placements of SPS units are also described.

Specifically, this disclosure describes a portable or transportable solar photovoltaic (PV) electricity generator module (i.e., the RDP-SPG module) comprising a plurality of smart power slat (SPS) units or building blocks, each SPS unit comprising a plurality of partitioned solar cells electrically connected together based on a specified solar cell partitioning pattern and electrical interconnection design, and, at least one multi-modal power-maximizing semiconductor integrated circuit collecting and delivering electricity generated by the plurality of solar cells according to a distributed power-maximizing architecture. Besides the RDP-SPG module open designs (i.e., pivoting/hinging design with end frames or electro-mechanical connecting units connecting the adjacent SPS building blocks), this disclosure also describes an alternative SPS-on-SPS sliding design that creates a closed-format structure in the fully expanded/deployed mode of operation (i.e., creating a segmented planar or curved bifacial module with a smaller deployed volume but with a higher wind resistance due to its closed design). The electrical power leads of each RDP-SPG module or a plurality of electrically-connected RDP-SPG modules are attached to a module-scale or system-scale MPPT charge controller (or MPPT controller/power optimizer, converter, inverter, and/or regulator)

### BRIEF DESCRIPTION OF THE DRAWINGS

The following description and associated figures teach illustrative embodiments of the disclosure. For the purpose of teaching inventive principles, some conventional aspects of the illustrative examples can be simplified or omitted. The claims should be considered as part of the disclosure. Note that some aspects of the best mode may not fall within the scope of the disclosure as specified by the claims. Thus, those skilled in the art will appreciate variations from the claimed embodiments that fall within the scope of the disclosure. Those skilled in the art will appreciate that the features described below can be combined in various ways to form multiple variations of the disclosure. As a result, the disclosure is not limited to the specific examples described below.

Please note that in the figures, relative geometrical dimensions are not shown to scale.

The above aspects and other aspects and features will become apparent to those ordinarily skilled in the art upon review of the following description of specific embodiments in conjunction with the accompanying figures, wherein:

FIG. 1A illustrates an example auxiliary three-dimensional view 100A of a slatted bifacial SPG module placed in a retracted form (non-power-generation mode), and capable of being rapidly deployed for power generation as a gravity-oriented and vertically-oriented module.

FIG. 1B illustrates an example top view100B of a slatted bifacial SPG module placed in a retracted form (non-power-generation mode), and capable of being rapidly deployed for power generation as a gravity-oriented and vertically-oriented module, according to the present disclosure.

FIG. 2 illustrates an example auxiliary three-dimensional view 200 of an SPG module in fully expanded form deployed along the vertical orientation (or along the force of gravity) by the force of gravity when anchored or hung from it top, in accordance with teachings of the present disclosure.

FIG. 3A illustrates an example view 300A of an SPG module 202 in a fully retracted or compacted form (non-power-generating mode), according to the present disclosure.

FIG. 3B illustrates an example 300B of an SPG module in a partially expanded form (not deployed vertically along the force of gravity orientation yet) according to the present disclosure.

FIG. 3C illustrates an example an example 300C of an SPG module in a fully expanded form (not deployed vertically along the force of gravity orientation yet) according to the present disclosure.

FIG. 4 illustrates an example 400 of an SPG module in a retracted, partially expanded, and fully expanded forms alongside each other.

FIG. 5A illustrates an example embodiment 500A of an SPG module in a fully retracted form (non-power-generating mode) anchored and attached to an airborne drone, according to the present disclosure.

FIG. 5B illustrates an example embodiment 500B of an SPG module in a fully expanded and gravity-oriented deployed form anchored or attached to an airborne drone for in-flight electricity generation, according to the present disclosure.

FIG. 6A illustrates an example embodiment 600A of an SPG module in a retracted form (non-power-generating mode) anchored and attached to a building window frame, according to the present disclosure.

FIG. 6B illustrates an example embodiment 600B of an SPG module in a fully expanded and gravity-oriented deployed form anchored and attached to a building window frame for electricity generation, according to the present disclosure.

FIG. 7 illustrates an example embodiment 700 of a plurality of SPG modules in expanded and gravity-oriented deployed forms anchored and attached to a greenhouse structure for electricity generation, according to the present disclosure.

FIG. 8 illustrates an example 800 of a side view of SPG modules anchored and attached to an electric vehicle (car), in an expanded and vertically deployed form for on-board electric vehicle (car) charging via solar electricity generation, according to the present disclosure.

FIG. 9 illustrates an example 900 of a side view of SPG modules anchored and attached to an electric vehicle (car), in a fully retracted form (non-electricity-generating mode) for on-board electric vehicle (car) charging (whenever expanded and deployed for electricity generation), according to the present disclosure.

FIG. 10 illustrates an example 1000 of a side view of a plurality of SPG modules anchored and attached to an electric bus, in an expanded and vertically-deployed form such as gravity-oriented form for on-board electric bus charging via solar electricity generation, according to the present disclosure.

FIG. 11 illustrates an example 1100 of a plurality of SPG modules in an expanded form, vertically deployed along the force of gravity and hanging over and co-located with an outdoor agricultural field for solar electricity generation, according to the present disclosure.

FIG. 12 illustrates an example 1200 SPG modules in an expanded form, vertically deployed along the force of gravity, attached to and hanging from a street light pole, an electricity distribution pole, and an electricity distribution tower, according to the present disclosure.

FIG. 13 illustrates an example 1300 of various (top, short side, and long side) views of a closed-format (no spacing between adjacent SPS units) architecture for an ultra-lightweight RDP-SPG module with a high surface compaction ratio (ratio of total surface area between deployed/expanded and retracted states), according to the present disclosure.

FIG. 14 illustrates an example 1400 of a plan view of an ultra-lightweight RDP-SPG module with a high surface compaction ratio (ratio of total surface area between its expanded and retracted states) deployed in a fully expanded form with the SPS units pulled apart from each other, according to the present disclosure.

FIG. 15 illustrates an example 1500 of cross-sectional side view of an ultra-lightweight RDP-SPG module with a high surface compaction ratio showing the interconnecting edge guide rails (sliding electro-structural or electro-mechanical connectors) on the SPS building blocks, according to the present disclosure.

FIG. 16 illustrates a first example design layout 1600 of an SPS laminate building block including a plurality of electrically connected partitioned sub-cells nested within an in-laminate frame and embedded within the laminate, providing both the positive and negative electrical power leads on both the shorter ends of the SPS laminate building block, according to the present disclosure.

FIG. 17 illustrates a first example 1700 of electro-structural (or electro-mechanical) connector, comprising a retractable & expandable structural connector part also having electrical interconnections (such as copper ribbons) for connections of the electrical power leads between any two adjacent SPS building blocks of FIG. 16, according to the present disclosure.

FIG. 18 illustrates a second example 1800 of electro-structural (or electro-mechanical) connector, comprising a retractable & expandable structural connector part also having electrical interconnections (such as copper ribbons) for connections of the electrical power leads between any two adjacent SPS building blocks of FIG. 16, and further providing additional end-to-end long-range connectors and additional connector leads, according to the present disclosure.

FIG. 19 illustrates a second example design layout 1900 of an SPS laminate building block including a plurality of electrically connected partitioned sub-cells nested within an in-laminate frame and embedded within the laminate, providing both the positive and negative electrical power leads on only one of the shorter ends of the SPS laminate building block, according to the present disclosure.

FIG. 20 illustrates an example 2000 of electro-structural (or electro-mechanical) connector, comprising a retractable & expandable structural connector part also having electrical interconnections (such as copper ribbons) for connections of the electrical power leads between any two adjacent SPS building blocks of FIG. 19, according to the present disclosure.

FIG. 21 illustrates a third example design layout 2100 of an SPS laminate building block including a plurality of electrically connected partitioned sub-cells nested within an in-laminate frame and embedded within the laminate, providing both the positive and negative electrical power leads only on one of the shorter ends of the SPS laminate building block, and further providing additional end-to-end long-range connectors and additional connector leads, according to the present disclosure.

FIG. 22 illustrates an example 2200 of electro-structural (or electro-mechanical) connector, comprising a retractable & expandable structural connector part also having electrical interconnections (such as copper ribbons) for connections of the electrical power leads between any two adjacent SPS building blocks of FIG. 21, and further providing additional end-to-end long-range connectors and additional connector leads, according to the present disclosure (design is similar to FIG. 18).

FIG. 23 illustrates a fourth example design layout 2300 of an SPS laminate building block including a plurality of electrically connected partitioned sub-cells nested within an in-laminate frame and embedded within the laminate, providing the positive electrical power lead on one of the shorter ends and the negative electrical power lead on the opposite shorter end of the SPS laminate building block (positive on one end and negative on the opposite end), according to the present disclosure.

FIG. 24 illustrates an example 2400 of electro-structural (or electro-mechanical) connector, comprising a retractable & expandable structural connector part also having electrical interconnections (such as copper ribbons) for connections of the electrical power leads between any two adjacent SPS building blocks of FIG. 23, according to the present disclosure.

FIG. 25 illustrates a fifth example 2500 of an SPS laminate building block including a plurality of electrically connected partitioned sub-cells nested within an in-laminate frame and embedded within the laminate, providing the positive electrical power lead on one of the shorter ends and the negative electrical power lead on the opposite shorter end of the SPS laminate building block, and further providing additional end-to-end long-range connectors and additional connector leads, according to the present disclosure.

FIG. 26 illustrates an example 2600 of electro-structural (or electro-mechanical) connector, comprising a retractable & expandable structural connector part also having electrical interconnections (such as copper ribbons) for connections of the electrical power leads between any two adjacent SPS building blocks of FIG. 23, and further providing additional end-to-end long-range connectors and additional connector leads, according to the present disclosure. This design may use only a subset of the copper ribbons and hinge landing pads shown. There is some redundancy in the hinge pads and copper ribbons for added SPS interconnection flexibility. Furthermore, all conductor pads and runners required on one face of the connector frames as shown. This design provides additional conductor ribbons for long-range interconnections.

FIG. 27A illustrates an example cross-sectional view 2700A of a first example design layout for single SPS laminate along the short axis of the SPS laminate including a plurality of structural ribs built into the in-laminate frame, according to the present disclosure.

FIG. 27B illustrates an example plan view 2700B of the single SPS laminate of FIG. 27 A including a plurality of structural ribs built into the in-laminate frame, according to the present disclosure.

FIG. 27C illustrates an example cross-sectional view 2700C of the single SPS laminate of FIG. 27A along the long axis of the SPS laminate including a plurality of structural ribs built into the in-laminate frame, according to the present disclosure.

FIG. 28A illustrates an example cross-sectional view 2800A of a stack of plurality of SPS laminates of FIG. 27A along the short axis of the SPS laminates, each including a plurality of interleaved structural ribs built into the in-laminate frame, according to the present disclosure.

FIG. 28B illustrates an example plan view 2800B of a stack of plurality of SPS laminates of FIG. 27A, each including a plurality of interleaved structural ribs built into the in-laminate frame, according to the present disclosure.

FIG. 28C illustrates an example cross-sectional view 2800C of a stack of plurality of SPS laminates of FIG. 27 along the long axis of the SPS laminates, each including a plurality of interleaved structural ribs built into the in-laminate frame, according to the present disclosure.

FIG. 29A illustrates an example cross-sectional view 2900A of a second example design layout for a single SPS laminate along the short axis of the SPS laminate, including a plurality of structural ribs and perforations built into the in-laminate frame, according to the present disclosure.

FIG. 29B illustrates an example plan view 2700B of the second example design layout for the single SPS laminate of FIG. 29A including a plurality of structural ribs and perforations built into the in-laminate frame, according to the present disclosure.

FIG. 29C illustrates an example cross-sectional view 2900C of the second example design layout for the single SPS laminate of FIG. 29A along the long axis of the SPS laminate, including a plurality of structural ribs and perforations built into the in-laminate frame, according to the present disclosure.

FIG. 30A illustrates an example cross-sectional view 3000A of a stack of plurality of SPS laminates of FIG. 29A along the short axis of the SPS laminates, each including a plurality of interleaved structural ribs and perforations built into the in-laminate frame, according to the present disclosure.

FIG. 30B illustrates an example plan view 3000B of a stack of plurality of SPS laminates of FIG. 29A, each including a plurality of interleaved structural ribs and perforations built into the in-laminate frame, according to the present disclosure.

FIG. 30C illustrates an example cross-sectional view 3000C of a stack of plurality of SPS laminates of FIG. 30 along the long axis of the SPS laminates, each including a plurality of interleaved structural ribs and perforations built into the in-laminate frame, according to the present disclosure.

FIG. 31 illustrates an example 3100 of an open structure SPG module design, with non-adjustable fixed-tilt SPS units shown as being perpendicular to the large virtual planes, according to the present disclosure.

FIG. 32 illustrates an example 3200 of an open structure SPG module design, with non-adjustable fixed-tilt SPS units shown as being non-perpendicular to the large virtual planes, according to the present disclosure.

FIG. 33A illustrates an example side view 3300A of an SPG module design, enabling manual SPS tilt adjustment for SPS units, with the SPS tilt angles shown as perpendicular to the large virtual planes, according to the present disclosure.

FIG. 33B illustrates an example top view 3300B of an SPG module design, enabling manual SPS tilt adjustment for SPS units, with the SPS tilt angles shown as perpendicular to the large virtual planes, according to the present disclosure.

FIG. 34A illustrates an example side view 3400A of an SPG module design, enabling manual SPS tilt adjustment for SPS units, with the SPS tilt angles shown as non-perpendicular to the large virtual planes, according to the present disclosure.

FIG. 34B illustrates an example top view 3400B of an SPG module design, enabling manual SPS tilt adjustment for SPS units, with SPS the tilt angles shown as non-perpendicular to the large virtual planes, according to the present disclosure.

FIG. 35 illustrates a three-dimensional perspective of the representative example shown in the side view of FIG. 33A and top view of FIG. 33B, in accordance with the teachings of the present disclosure.

FIG. 36 illustrates a three-dimensional perspective of the representative example shown in the side view of FIG. 34A and top view of FIG. 34B, in accordance with the teachings of the present disclosure.

FIG. 37 illustrates a first example 3700 of representative dimensions for an SPS building block comprising co-planar partitioned series-connected sub-cells (in this example, there are 12 sub-cells prepared by partitioning each full-size solar cell into 8×2=16 equal-area sub-cells and using 12 of such sub-cells made from 1.5 full-size cells), according to the present disclosure.

FIG. 38 illustrates a first example 3800 of representative dimensions for an SPS building block comprising overlapping partitioned series-connected sub-cells (in this example, there are 12 sub-cells prepared by partitioning each full-size solar cell into 8×2=16 equal-area sub-cells and using 12 of such sub-cells made from 1.5 full-size cells), according to the present disclosure.

FIG. 39 illustrates a second example 3900 of representative dimensions for an SPS building block comprising co-planar partitioned series-connected sub-cells (in this example, there are 12 sub-cells prepared by partitioning each of 2 full-size solar cells into 6 equal-area sub-cells), according to the present disclosure.

FIG. 40 illustrates a second example 4000 of representative dimensions for an SPS building block comprising overlapping partitioned series-connected sub-cells (in this example, there are 12 sub-cells prepared by partitioning each of 2 full-size solar cells into 6 equal-area sub-cells), according to the present disclosure.

FIG. 41 illustrates a third example 4100 of representative dimensions for an SPS building block comprising co-planar partitioned series-connected sub-cells (in this example, there are 12 sub-cells prepared by partitioning each of 3 full-size solar cells into 4 equal-area sub-cells), according to the present disclosure.

FIG. 42 illustrates a third example 4200 of representative dimensions for an SPS building block comprising overlapping partitioned series-connected sub-cells (in this example, there are 12 sub-cells prepared by partitioning each of 3 full-size solar cells into 4 equal-area sub-cells), according to the present disclosure.

FIG. 43 illustrates an example 4300 of the schematic diagram of an SPS building block of FIG. 41 or FIG. 42, including the schematic electrical wiring diagram, comprising a single super cell, with said super-cell comprising 3×4=12 sub-cells, and a single multi-modal MPPT IC for distributed power maximization, according to the present disclosure.

FIG. 44 illustrates a fourth example 4400 of representative dimensions for an SPS building block comprising co-planar partitioned series-connected sub-cells (in this example, there are 12 sub-cells prepared by partitioning each of 4 full-size solar cells into 3 equal-area sub-cells), according to the present disclosure.

FIG. 45 illustrates a fourth example 4500 of representative dimensions for an SPS building block comprising overlapping partitioned series-connected sub-cells (in this example, there are 12 sub-cells prepared by partitioning each of 4 full-size solar cells into 3 equal-area sub-cells), according to the present disclosure.

FIG. 46 illustrates an example 4600 of the schematic diagram of an SPS building block of FIG. 44 or FIG. 45, including the schematic electrical wiring diagram, comprising a single super cell, with said super-cell comprising 4×3=12 sub-cells, and a single multi-modal MPPT IC for distributed power maximization, according to the present disclosure.

### DETAILED DESCRIPTION OF THE EMBODIMENTS

Embodiments of the present disclosure will now be described in detail with reference to the drawings, which are provided as illustrative examples so as to enable those skilled in the art to practice the embodiments.

Notably, the figures and examples below are not meant to limit the scope to a single embodiment, but other embodiments are possible by way of interchange of some or all of the described or illustrated elements. Where certain elements of these embodiments can be partially or fully implemented using known components, only those portions of such known components that are necessary for an understanding of the embodiments will be described, and detailed descriptions of other portions of such known components will be omitted so as not to obscure the description of the embodiments.

In the present specification, an embodiment showing a singular component should not be considered limiting; rather, the scope is intended to encompass other embodiments including a plurality of the same component, and vice-versa, unless explicitly stated otherwise herein. Moreover, applicants do not intend for any in the specification or claims to be ascribed an uncommon or special meaning unless explicitly set forth as such. Further, the scope encompasses present and future known equivalents to components referred to herein by way of illustration.

As states earlier in the specification, described herein are various structures and manufacturing methods for Rapidly Deployable & Portable Smart Power Generators (abbreviated as “RDP-SPG” and sometimes referred to as SPG or also as generator modules) comprising a plurality of modular and scalable bifacial photovoltaic electric power-generating building blocks, known as Smart Power Slat (SPS) units or SPS building blocks.

Typically, the mainstream glass-covered solar photovoltaic generation modules are not easily portable or easily deployable and also require a relatively large installation footprint (covering a relatively large installation area on the ground).

The proposed solution effectively addresses this problem by teaching an apparatus and a method of making RDP-SPG modules which are easily deployable as vertically-oriented or gravity-oriented modules substantially along the force of earth gravity for various applications.

In the following specification, the term “SPG (Smart Power Generation) module” may be alternatively used with the term “module” for the module architectures of this disclosure. Also the term “form” may be alternately used with the term “state”. Further, the term connectors may be alternately used with the term connector plates or end plates or connector segments or sheet segments or pivoting or hinging or folding electromechanical (also known as electro-structural) connectors.

The slatted bifacial module architecture according to the present disclosure comprises a plurality of bifacial Smart Power Slat (SPS) building blocks. Each SPS further may have a plurality of partitioned (such as laser-partitioned) bifacial solar cells (including bifacial monocrystalline solar cells such as bifacial monocrystalline PERC, PERT, or heterojunction solar cells) and may have at least a single Maximum Power Point Tracking (MPPT) integrated circuit (IC), specifically an in-laminate multi-modal power-maximizing MPPT IC having a relatively thin (<1 mm) IC package and being powered by the SPS photovoltaic power. The gravity-oriented and vertically-oriented slatted bifacial smart power generation (SPG) modules, hereafter SPG modules, per this disclosure are RDP-SPG modules which can be easily and rapidly retracted into a very compact volume and reduced overall surface area (portable non-deployed and non-power-generating state) and expanded into a gravity-oriented and vertically-oriented (with the deployment expansion axis substantially along and parallel to the force of gravity) deployed solar power generation mode for the intended power generation applications.

In the gravity-oriented and vertically-oriented deployed photovoltaic power generation mode, the longer axes (the axes along the longer dimensions of the thin SPS building blocks which are along the photovoltaic electrical current flow direction in each SPS unit) of the SPS building blocks are substantially parallel to each other and preferably (but not necessarily) perpendicular to the gravitational force (the module is hanging while being supported or anchored from its topside, or vertically oriented while being lifted and supported from its bottom side).

Furthermore, in the gravity-oriented and vertically-oriented deployed photovoltaic power generation mode, the planes of the SPS building blocks may be either substantially parallel to the earth surface (i.e., perpendicular to the gravity force with 90° angle between the SPS plane and the force of gravity) or tilted with a specified tilt angle with respect to the earth's gravity force (non-perpendicular to the gravity force with the SPS units being non-parallel to the earth's surface).

The portable, lightweight, high-power-density gravity-oriented (or vertically-oriented) solar electric power generation systems of this disclosure are based on the rapidly portable and deployable module designs disclosed and described in the U.S. Provisional Application No. 62/483,333 titled “Rapidly Deployable and Transportable High-Power-Density Smart Power Generators”, filed Apr. 8, 2017 and U.S. Provisional Application No. 62/521,306 titled “Portable Agile Smart Power Generation Systems”, filed Jun. 16, 2017, and U.S. Provisional Application No. 62/528,934 titled “Gravity-Oriented and Vertically-Oriented High-Power-Density Portable Slatted Bifacial Power Generators”, filed Jul. 5, 2017, the disclosures of which are incorporated by reference herein.

In one example, the gravity-oriented and vertically-oriented solar electric power generation module of this disclosure has a plurality of bifacial SPS building blocks which are preferably relatively thin, planar and parallel to each other.

Each SPS building block is a bifacial solar power generation building block which is made of a plurality of partitioned (such as laser partitioned) and electrically-interconnected (with at least some connected in electrical series) bifacial solar cells (such as bifacial monocrystalline silicon solar cells manufactured based on the PERC, PERT, heterojunction, or some other suitable high-efficiency technology to provide solar cells with at least 19% conversion efficiency), encapsulated between two protective transparent cover sheets (e.g., fluoropolymer cover sheets such as ethylene tetrafluoroethylene or ETFE, or fluorinated ethylene propylene or FEP) on both sides using embedded encapsulant material on both sides, and further supported by an in-laminate frame made of a lightweight electrically-insulating strong fiber-reinforced composite polymeric material (such as glass-filled nylon). When expanded and deployed in the gravity-oriented or vertically-oriented power generation mode, the planes of the SPS units may be either perpendicular to the gravity force or have a non-perpendicular orientation or tilt angle with respect to the gravity force (with the tilt angle optimized for maximum electricity generation yield); the SPS tilt angles may be either fixed by the design or may even be adjustable in real time through a simple mechanical adjustment mechanism.

If the module of this disclosure provides SPS tilt adjustment capability, SPS tilt adjustment may be manual or automated and may be used to further enhance power generation (or cumulative electricity generation yield) through a very simple, reliable, distributed real-time tracking.

The bifacial SPG modules as taught by this disclosure provide several advantages some of which are mentioned below. The SPG These modules generate the electric power by harvesting the sunlight along the perpendicular orientation or vertical Z axis along the force of gravity (long plane axes of Smart Power Slats substantially perpendicular to the gravity force) enables applications requiring relatively small horizontal module deployment footprints and/or deployment while being anchored and hung from the topside of the module.

The SPG modules of this disclosure also enable on-board in-flight electric power generation on the scale of 10's of watts up to several kilo-watts and more in airborne vehicles (e.g., drones and balloons), while requiring very small lateral (horizontal) footprint and providing allowance for full retraction into a very small volume and footprint for landing and full expansion for maximum gravity-oriented and vertically-oriented electric power generation in flight. The SPG modules of this disclosure also enables electric power generation as hanging commercial and residential building window covers anchored from the top, requiring negligible horizontal footprint (taking vertical space instead of consuming horizontal footprint).

Full extension and gravity-oriented (or vertically-oriented) deployment can be done using the gravity force by simply extending or releasing a cord attached to the lowest slat (such as in a blind window covering). Full module retraction & compaction can be done by simply pulling a cord or string attached to the lowest slat. The SPG modules of this disclosure also enable a range of other footprint-constrained and/or weight-constrained applications such as on agricultural lands, greenhouses, hanging modules from street light poles, electricity distribution poles, electricity transmission towers, telecommunication poles, telecommunication cell towers, architectural BIPV such as hanging on the sides of buildings and/or hanging from ceilings of buildings with transparent ETFE membrane roofs, etc.

In its simplest embodiment, the gravity-oriented and vertically-oriented slatted bifacial module design as taught by this disclosure utilizes pivoting or hinging or folding electromechanical (also known as electro-structural) connectors between the adjacent bifacial SPS building blocks i.e. wherein the connectors are fully extended under the gravity force when the module is hung by anchoring and supporting it from its topside such as from its topmost SPS building block, or wherein the electromechanical (electro-structural) connectors are fully retracted under the gravity force when the module is not anchored and sits on a supporting surface (the SPS building blocks are stacked in a small volume by the gravity force, resulting in a fully retracted/compacted module for portable state). The electromechanical or electro-structural connectors provide the dual functions of structural connections and electrical connections between adjacent SPS building blocks and among the entire plurality of SPS building blocks in the SPG module.

In this embodiment for a deployed gravity-oriented (vertically-oriented) slatted module (anchored & hung from its top), the planes of the SPS building blocks, which are parallel to one another, have fixed (and optionally adjustable) tilt angles with respect to the horizontal plane or the force of gravity:

In one design option, the planes of the SPS building blocks are substantially perpendicular to the force of gravity (i.e., parallel to the horizontal plane with the SPS plane-to-gravity force tilt angle of 90°)

In another design option, the planes of the SPS building blocks are non-perpendicular to the force of gravity (i.e., tilted and non-parallel with respect to the horizontal plane)

In one example, the gravity-oriented (or vertically-deployed) hanging-mode deployment of slatted bifacial modules utilize the vertical footprint instead of lateral or horizontal footprint (like vertical gardens instead of regular gardens), do not occupy any significant regular footprint or land area for indoor or outdoor operation since they are anchored and hanging from their topsides (and typically also raised above ground); therefore, no lateral or horizontal land area is occupied (or the usage of horizontal area is rather small). Further, the gravity-oriented (hanging-mode and vertically-oriented bi-facial) slatted modules may be deployed for photovoltaic power generation very easily, for instance, by simply using anchoring or hanging cords from their topsides. The cords serve as a mechanical or structural support and also provide electrical wiring connections in order to deliver the module power to a load. The gravity-oriented (hanging-mode or vertically-oriented) slatted bifacial modules of this disclosure are not subject to and do not block people movement or vehicle traffic in indoor and outdoor applications. Moreover, in outdoor applications, the open-structure designs of this disclosure do not retain any rain water or snow and experience negligible wind resistance. These modules are also self-cleaning and do not require maintenance or cleaning.

The gravity-oriented (hanging-mode or vertically oriented) slatted bifacial modules of this disclosure may optionally provide simple capabilities for manual or automated simple distributed sunlight tracking through one or a combination of simultaneous angular rotations of the entire plurality of SPS units and adjustment of the tilt angles of the SPS building blocks (the planes of the SPS units preferably remain parallel to one another for any tilt angle) as will be explained in more details later during the specification.

The gravity-orientated or vertically-oriented RDP-SPG modules of this disclosure can also be used for on-board electric power generation in airborne vehicles such as airborne drones or balloons, being fully expanded into the gravity-oriented direction (longer plane axes of the SPS building blocks being perpendicular to the gravity force), while capable of being fully retracted into very compact volume and exposed surface area upon take-off and landing.

The airborne vehicles which can use the gravity-oriented high-power-density portable slatted bifacial power generators (having the RDP-SPG modules) of this disclosure as on-board power generators include electric drones, airplanes, and balloons used for a variety of applications including wireless internet access anywhere, commercial drones used for delivering merchandise, and continuously-flying (for weeks or months at a time) surveillance or weather drones.

The airborne vehicle can take off with the gravity-oriented high-power-density portable slatted bifacial power generator of this disclosure anchored to or hanging from its bottom and initially in a fully retracted (compact) state; after being airborne, the vehicle can deploy the on-board RDP-SPG module by allowing it to expand and be deployed and oriented by the gravity force. When the airborne vehicle is landing, it retracts the on-board gravity-orientated RDP-SPG module into its fully retracted and compact state prior to landing. For airborne applications, the gravity-orientation RDP-SPG modules of this disclosure can be combined with on-board high-energy-density battery storage for continuous uninterrupted power supply.

In another embodiment this disclosure teaches a vertically-deployable and retractable slatted RDP-SPG module (comprising a plurality of Smart Power Slats or SPS units as disclosed and described in the earlier related provisional patent application), wherein the module is anchored and supported at its bottom (instead of being hung from its topside).

Full retraction of the vertically-deployable and retractable slatted bifacial RDP-SPG module in this embodiment results in compaction of the module by moving the slats or SPS building blocks downward (in the direction of the gravity force) towards the bottom anchoring/support region and stacking them on top of one another for full compaction of volume and surface area (non-power-generating state).

Partial and full expansion of the vertically-deployable & retractable slatted RDP-SPG module in this embodiment results in expansion of the module by moving the slats or SPS building blocks upward (substantially parallel to and opposite the gravity force direction) away from the bottom anchoring/support region and spacing them apart from one another to enable efficient light capture on both faces of the bifacial SPS building blocks and photovoltaic power generation by the vertically-deployed RDP-SPG module (partial and full expansion result in lower and higher power generation, respectively)

This vertically-deployable & retractable slatted RDP-SPG module embodiment is applicable in applications requiring deployment in a constrained lateral footprint area for electric power generation, while not providing an allowance for anchoring/hanging the slatted module from its topside

As stated earlier this disclosure also describes an apparatus for ultra-lightweight RDP-SPG modules with a high compaction ratio, primary features and attributes of which are explained below.

This alternative slatted bifacial module design (also referred to as sliding design), cable of retraction and expansion with high compaction ratio, is also based on using bifacial Smart Power Slat (SPS) building blocks, the same SPS building blocks used for the primary RDP-SPG module designs. Each bifacial SPS building block has at least one multi-modal MPPT integrated circuit electrically attached to it or laminated within its laminate for distributed power optimization and maximization in the RDP-SPG module.

An RDP-SPG module has a plurality (with an integer count number U) of SPS building blocks (e.g., typically U=2 to over 50 SPS units in an SPG module). In the fully retracted mode, the SPS building blocks are fully stacked on each other, creating a very compact (in terms of volume and exterior surface area for shipping, storage, and portability) and lightweight portable module.

In the fully expanded mode for power generation, the SPS building blocks are spread open by sliding them via the guides and rails mounted on the shorter sides of the SPS building blocks, fully exposing the bifacial power generating surfaces of the SPS units for deployment mode operation.

In contrast to the primary RDP-SPG module open-structure or open-format designs (i.e., pivoting/hinging/folding design with end electro-structural or electromechanical connectors connecting the adjacent SPS building blocks), this alternative sliding design creates a closed-format structure in the fully expanded/deployed mode of operation (creating a segmented planar or curved bifacial module with a smaller deployed volume but a higher wind resistance due to its closed-format structure not providing open pathways for wind to blow through)

The electrical power leads of each RDP-SPG module or a plurality of electrically-connected RDP-SPG modules are attached to an MPPT charge controller (or MPPT controller, DC-DC converter, regulator, and/or DC-AC inverter) This disclosure also teaches an alternative architecture (design) for ultra-lightweight RDP-SPG modules with high-compaction ratio and electromechanical or electro-structural connections among the SPS building blocks. In one example, this alternative design is a sliding design. In this alternative sliding design, electromechanical or electro-structural connections among various SPS building blocks are also crucial.

In some examples, as will be seen, the SPS building blocks are rectangular shaped include electro-structural rails and guides (commonly known in the art). The pairs of rails and guides on the shorter sides of the SPS building blocks provide the dual functions of mechanical (or structural) and electrical connections between the adjacent SPS units.

In each SPS building block, a guide rail on a shorter side and a guide cavity on the other shorter side may be metallized with electrical connections to the positive and negative electrical leads of the SPS building block (for instance, the guide rail on the first shorter side is connected to the SPS positive serving as its positive lead, and the guide cavity on the second shorter side is connected to the SPS negative serving as its negative lead in order to connect the adjacent SPS units in electrical series).

Using the above-mentioned arrangement, a group of SPS building blocks may be connected in electrical series, with the rail on the first SPS unit and the cavity on the last SPS unit of the RDP-SPG module serving as the RDP-SPG module electrical leads (series-connected SPS building blocks)

Other rail & guide mechanical & electrical designs and arrangements are possible in the sliding design architecture for electromechanical (or electro-structural) interconnections of SPS building blocks

Also important and described are electromechanical (or electro-structural) interconnections among the SPS building blocks of the open-structure using a suitable hinging/pivoting/folding electro-structural design for RDP-SPG modules.

Depending on the power scale and other design features of the Rapidly Deployable and Portable Smart Power Generation (RDP-SPG) module and its target applications, the electrical interconnections among the SPS building blocks in an RDP-SPG module may be all-series, hybrid series-parallel, or even all-parallel.

The preferred SPS building blocks electrical interconnection designs in an RDP-SPG module are the all-series or hybrid series-parallel configurations, depending on various module design specifications and the target applications.

The maximum RDP-SPG module voltage (i.e., module open-circuit voltage or module Voc) should preferably be kept in a safe-to-touch zone, preferably limited to <70 V and more preferably to <50 V. However, higher maximum module voltages (up to 100's of volts) may be utilized in conjunction with taking the necessary safety precautions depending on the target application.

If the maximum open-circuit voltage (i.e., max Voc) of the SPS building block is 12×0.7=8.4 V (e.g., for an SPS with 12 series-connected sub-cells), a maximum of 6 SPS building blocks may be connected in series in an RDP-SPG module, while limiting the maximum open-circuit voltage (Voc) of the module to about 50V.

If an RDP-SPG module uses SPS building blocks with a maximum Voc of ∫8.4 V, higher power modules using more than six SPS building blocks can be configured in series-parallel configuration while keeping the maximum module voltage limited to ˜50 V; for instance, an RDP-SPG module with U=12 SPS units may be configured with each of two sets of 6 SPS buildings blocks connected in series and then the two sets connected in parallel in order to limit the overall maximum Voc of the module to ˜50 V.

The copper (and/or solderable aluminum) ribbons overlaid on and supported by the in-laminate SPS frames and also on the end connector frames can be configured to enable various electrical interconnection configurations for the RDP-SPG module (all-series, parallel-series, or all-parallel SPS interconnections in the module)

There are various design options for providing the power leads on each SPS building block as given below.

Design Option 1: Both the positive and negative power leads provided on both the shorter SPS sides and also on both the opposite bifacial faces of the in-laminate frame of the SPS building block (e.g., 4 positive power leads located near two corners of the shorter sides of the SPS unit, and 4 negative power leads located near the other two corners of the shorter sides of the SPS unit; two sets of 4 power leads on 2 opposite faces of the bifacial SPS). In this design, the positive and negative power leads are available on both the shorter sides of each SPS unit, and also on both the opposite bifacial faces of the in-laminate frame (near the corners), providing the most design flexibility for various SPS-to-SPS electrical connections.

Design Option 2: The positive and negative power leads provided on one shorter SPS side and also on both the opposite bifacial faces of the in-laminate frame of the SPS building block (e.g., 2 positive power leads located near one corners of one of the shorter sides of the SPS unit, and 2 negative power leads located near the other corner of the same shorter side of the SPS unit; two sets of 2 power leads on two opposite faces of the bifacial SPS). In this design, the positive and negative power leads are available on only one of the shorter sides of each SPS unit, and also on both the opposite bifacial faces of the in-laminate frame (near the two corners of the shorter side having the leads).

Design Option 3: The positive power lead provided on one shorter side and the negative power lead provided on the other shorter side, each lead polarity also provided on both the opposite bifacial faces of the in-laminate frame of the SPS building block (e.g., 2 positive leads located on one of the shorter sides, and 2 negative leads located on the other shorter side of the SPS unit; two sets of 2 power leads on two opposite faces of the bifacial SPS). In this design, the positive leads are available on one of the shorter sides and the negative leads are available on the other shorter side of each SPS unit, and also on both the opposite bifacial faces of the in-laminate frame.

Besides the SPS power leads, the in-laminate composite frames of SPS units may support additional end-to-end long-range electrical conductors (e.g., copper ribbons) to serve as global interconnections for the RDP-SPG module and for providing access to the RDP-SPG module positive and negative power leads on any one of the module corners (e.g., providing return paths for the module positive and/or negative power leads).

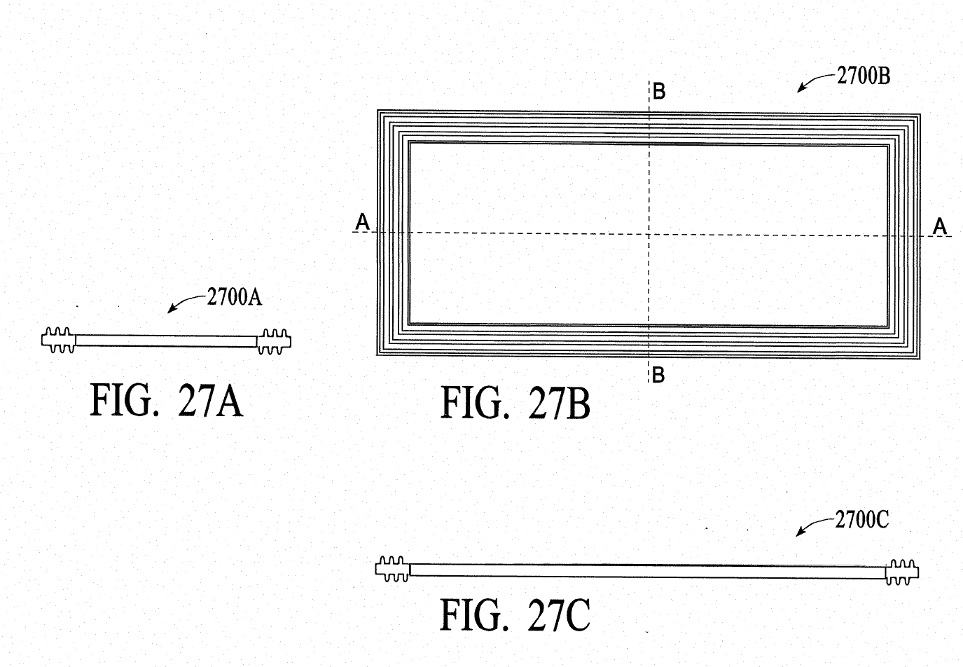

FIGS. 27-30 describe lightweight thin SPS in-laminate frame designs for maximizing the strength to weight ratio of the in-laminate frames and SPS building blocks according to this disclosure.

The SPS in-laminate frames are preferably relatively thin (e.g., <5 mm) single-piece parts made of suitable fiber-reinforced (e.g., glass-reinforced) composite plastics (e.g., suitable polymers such as polyamides or nylon mixed with glass fibers) using injection molding.

The preferred injection-moldable composite plastics (such as BASF's Ultramid Polyamides and Ultradur glass-filled fiber-reinforced plastic composites) have relatively low material densities (e.g., 1.39 g/cc for Ultramid® 8233G HS BK-106), hence, enabling production of ultra-light-weight, mechanically strong, and thin SPS building blocks.

The strength-to-weight ratio of the in-laminate frames (e.g., made of composite polymers, such as polyimides+glass fibers and/or glass particles, using injection molding) can be further enhanced by including structural ribs on one face or preferably both faces of the thin in-laminate frame structure.

In order to reduce the effect of the ribs on the overall thickness of the RDP-SPG module in the fully retracted state, the ribs on the two faces of the in-laminate frame may be offset with respect to each other such that the ribs on the two faces of an SPS are properly positioned (interleaved) in between the ribs of the adjacent SPS units when the RDP-SPG module is in the fully retracted and portable state (interleaved or nested ribs on the long sides and short sides of the frame).

Another approach to increase the strength-to-weight ratio of the in-laminate frame is using a perforated in-laminate frame structure (reducing the weight of the frame without an appreciable reduction of its mechanical strength).

Another approach for further increasing the strength-to-weight ratio of the in-laminate frame is to use the combination of the above-mentioned structures: ribbed structure combined with using perforations for further enhanced strength without increasing weight.

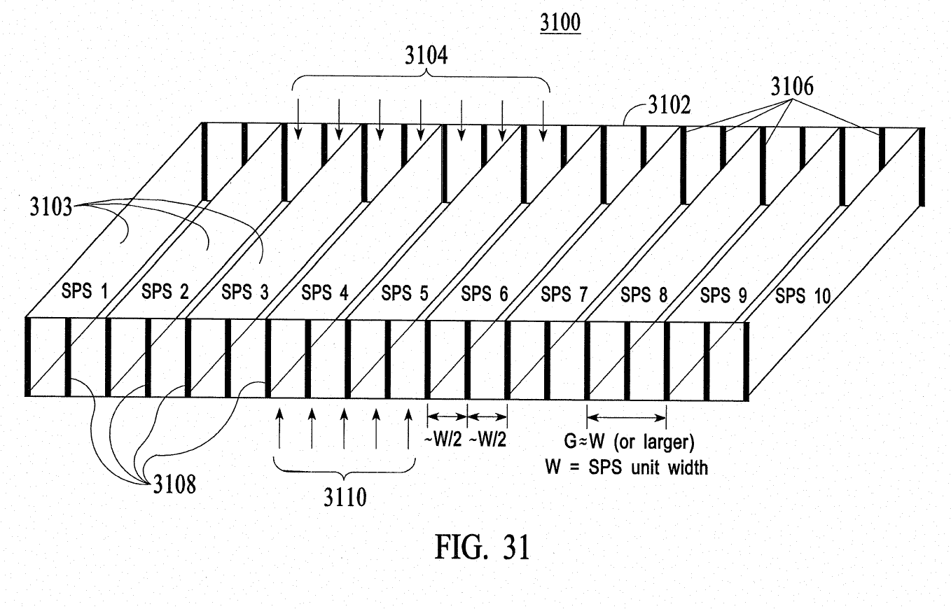

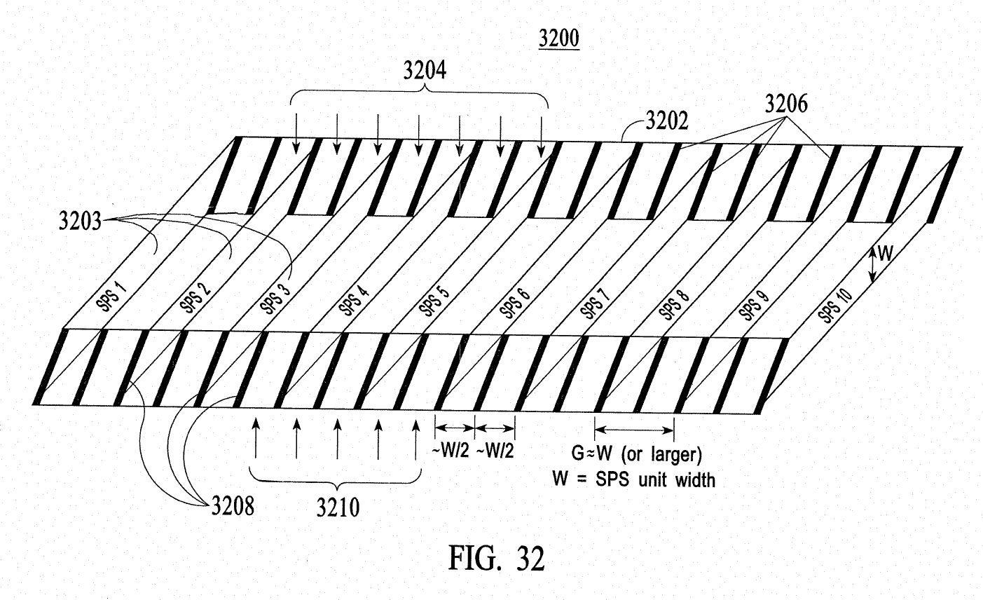

FIGS. 31-36 describe RDP-SPG modules of this disclosure along with various SPS electro-structural or electromechanical connector embodiments enabling fixed-tilt deployment as well as manual or automated SPS tilt control for the SPS building blocks of the open-structure rapidly deployable and portable smart power generation (RDP-SPG) modules of this disclosure.

The SPS tilt adjustment feature provides many benefits in the open-structure RDP-SPG modules. While it is not required to provide SPS tilt adjustment allowance in the RDP-SPG modules of this disclosure, in some applications it is beneficial to provide SPS tilt control capability for further enhanced electricity generation yield.

In the fixed-tilt-angle RDP-SPG module designs (two representative embodiments shown in the fully-extended state for deployment-mode power generation—see the relevant figures), the SPS building blocks are configured to be at a specified angle (preferably all of the SPS building blocks at the same fixed tilt angle) with respect to the virtual boundary planes of the extended RDP-SPG modules: either perpendicular or non-perpendicular to the virtual planes

Additional RDP-SPG design embodiments of this disclosure enable manual or automated adjustments of the tilt angles of the SPS building blocks (while keeping them substantially parallel to each other) with respect to the virtual boundary planes of the RDP-SPG module

The manual or automated SPS tilt angle adjustment capability can be used to maximize the power generation of the RDP-SPG module under various outdoor irradiance conditions. An automated mode of SPS tilt angle adjustment can be used to function as a real-time distributed sun-tracker to further enhance the deployment-mode energy generation of the RDP-SPG modules. For automated mode of SPS tilt angle adjustment, a small actuator/motor powered by the RDP-SPG module itself may be used in order to control the tilt angle to enhance power output.

One design approach to provide SPS tilt adjustment capability is to use four pairs of pivoting mechanical rods or thin rectangular plates between the shorter sides of adjacent SPS building blocks in an RDP-SPG module (two pivoting pairs on each end of the adjacent SPS units).

A relatively small linear movement of the pairs of pivoting mechanical rods or thin rectangular plates between the shorter sides of adjacent SPS building blocks can then be used to change the tilt angles of the SPS building blocks with respect to the virtual boundary planes of the RDP-SPG modules.

In some examples, the pivoting mechanical rods or thin rectangular plates connecting the adjacent SPS building blocks on their shorter sides can serve as both mechanical and electrical connectors between the adjacent SPS units, enabling the retraction and expansion of the RDP-SPG module and providing electrical interconnections among the SPS building blocks, connecting them in a desired all-series or hybrid series-parallel electrical arrangement.

In some examples, the pivoting mechanical rods or thin rectangular plates connecting the adjacent SPS building blocks on their shorter sides have hinging or pivoting or folding axes at their joints with the adjacent SPS building blocks, hence enabling rotation of each SPS unit with respect to every pivoting mechanical rod or thin rectangular plate, while maintaining the electrical and mechanical connections between the SPS units and the pairs of pivoting mechanical rods or thin rectangular plates between the shorter sides of adjacent SPS units in an RDP-SPG module . An embodiment according to present disclosure provides fully open structure when the RDP-SPG module is in the fully extended mode, enabling light access and capture by the SPS units from all directions. The disclosed RDP-SPG module designs enable manual SPS tilt adjustment using elongated pivoting connectors in a fully extended deployed state.

In one adjustable-tilt RDP-SPG module design embodiment of this this disclosure, there are two Rows 1 of electro-mechanical or electro-structural connectors and pivots (defining a first rectangular virtual boundary plane passing through the first set of SPS longer sides: to be called first large virtual boundary plane) and two Rows 2 electro-mechanical or electro-structural connectors and pivots (defining a second rectangular virtual boundary plane passing through the second set of SPS longer sides: to be called second large virtual boundary plane)

In this embodiment: one Row 1 one Row 2 on the first set of the shorter ends of the SPS building blocks define a first virtual boundary plane passing through these two rows (to be called “first small virtual boundary plane”); and the second Row 1 the second Row 2 on the second set of the shorter ends of the SPS building blocks define a second virtual boundary plane passing through these two rows (to be called second small virtual boundary plane)

When the relative linear displacements or offsets of Rows 1 with respect to Rows 2 are zero (i.e., the first small virtual boundary plane and the second small virtual boundary plane are rectangular-shaped, and the projection of the first large virtual boundary plane is fully aligned/overlapping with the projection of the second large virtual boundary plane), then the SPS building blocks are oriented perpendicular to the first and second virtual boundary planes

When the pair of Rows 1 and the pair of Rows 2 are linearly displaced with respect to each other (e.g., by applying a differential force between Rows 1 and Rows 2 to produce a linear offset), the tilt angles of the SPS building blocks with respect to the large virtual planes are changed from the perpendicular to non-perpendicular angles, with the SPS angles dependent on the linear displacement or offset value and the SPS building blocks being parallel to each other

When the linear displacement or offset value between the pairs of Rows 1 and Rows 2 is changed from zero to a finite non-zero value, the two small virtual boundary planes are changed from rectangular to non-right-angle parallelogram shapes and the SPS building blocks are tilted from perpendicular to non-perpendicular angles with respect to the large virtual boundary planes.

The tilt angles of the SPS building blocks with respect to the large virtual planes can be adjusted by changing the linear displacement or offset value between the pairs of Rows 1 and Rows 2, with larger offsets producing larger tilts.

Representative examples of various products using SPS building blocks of this disclosure include consumer chargers (phones, laptops, etc.), power for recreational vehicles (RVs) & boats, power for recreational outdoors & camping, on-board chargers for electric vehicles (EVs), power generators for military applications, power generators for emergency response, power generators for telecom cell towers, and various off-grid power generators.

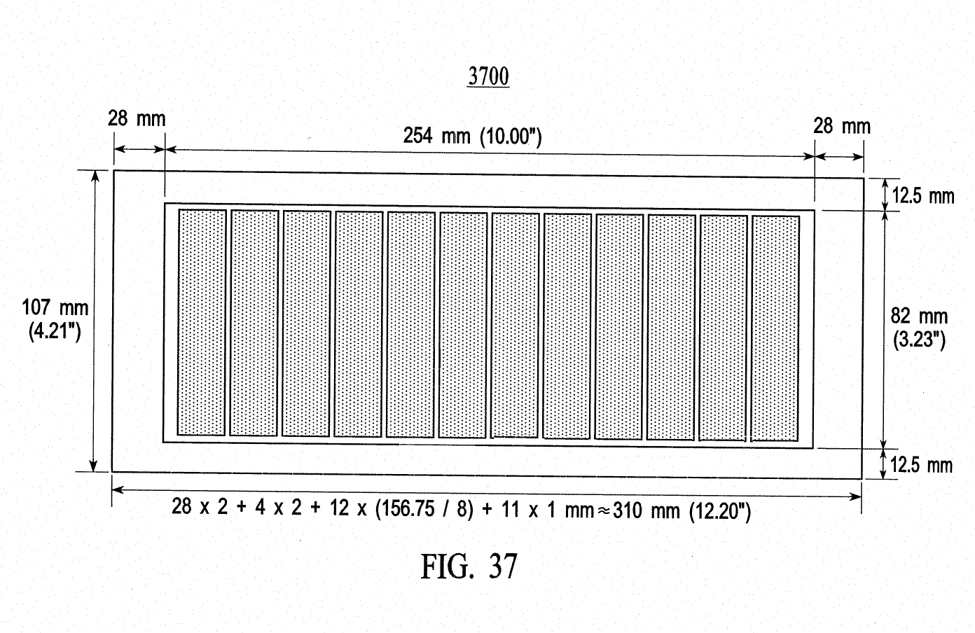

This disclosure also provides representative examples of RDP-SPG prototype builds. Some such examples of prototype RDP-SPG module types are described with respect to FIG. 37 to FIG. 46 explained later in the specification.

Also described with respect to FIG. 37 to FIG. 46 are multi-functional in-laminate composite frames for bifacial SPS building block units. The thin, lightweight, in-laminate frame of this disclosure can serve as one or a combination of several important functions in the bifacial SPS building block units. Some such functions include providing mechanical support, rigidity (or semi-rigidity), and planarity for the SPS building block units. Additionally, the multi-functional in-laminate frames provide a strong full-periphery mechanical edge protection to the SPS building block units. This offers protection to the laminated sub-cells to eliminate or suppress breakage or cracking of laminated sub-cells nested within the in-laminate frame. This also offers support to the substrate as a printed-circuit board for direct attachment of the multi-modal MPPT chip and related supporting parts (i.e., discrete capacitors), or alternatively support substrate for attachment of a small-footprint printed-circuit board having the MPPT chip and supporting parts pre-assembled on it. This also offers support to the substrate for copper foil ribbon runners for providing the SPS building block unit electrical leads (positive and/or negative leads) on one or both opposite ends of the SPS building block unit.

Furthermore, the multi-functional in-laminate frames may provide frame extensions on the opposite ends of the SPS building block unit for its mechanical attachment (such as easy plug-in or snap-in attachment, or attachment to electro-structural cords or strings) on the opposite sides of the SPS unit to the retractable and expandable mechanical & electrical connectors.

The multi-functional in-laminate frame may also provide electrical connector leads (i.e., the positive & negative electrical leads) supported by the frame extensions for electrical connections of the SPS building block unit to one or both of the retractable and expandable mechanical & electrical connectors (e.g., using plug-in or snap-in connectors).

The multi-functional in-laminate frame also providing hinging or pivoting or folding actions at the frame extensions on both the opposite ends of the SPS building block unit to enable retraction for module portability and expansion for module deployment.

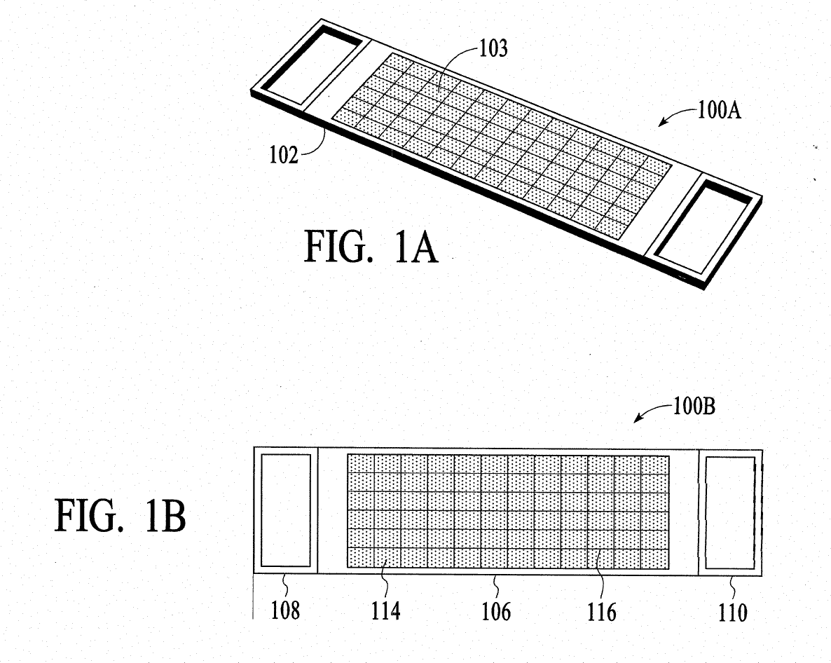

FIG. 1A illustrates an example auxiliary view 100A of a gravity-oriented and vertically-oriented slatted bifacial SPG module 102 in a retracted and compacted form, according to the present disclosure. The SPG module 102 comprises an SPS unit assembly 103. As shown the SPG module 102 is retracted when it is not anchored or hung from its topside or when it is sitting on the ground and retracted by the force of gravity). In the one example the SPG module 102 is self-retracting by gravitational force when it is not anchored or hung from its topside.

FIG. 1B illustrates an example top view100B of a gravity-oriented and vertically-oriented slatted bifacial SPG module 104, shown in a fully retracted form, according to the present disclosure. As shown the SPG module 104 includes an SPS unit assembly 106, and side handles, also referred to as connectors or electro-structural (electromechanical) connectors 112 108, 114 110. The SPS unit assembly comprises partitioned rectangular bifacial solar cells e.g., 108114, 110 116 within an in-laminate frame 112.

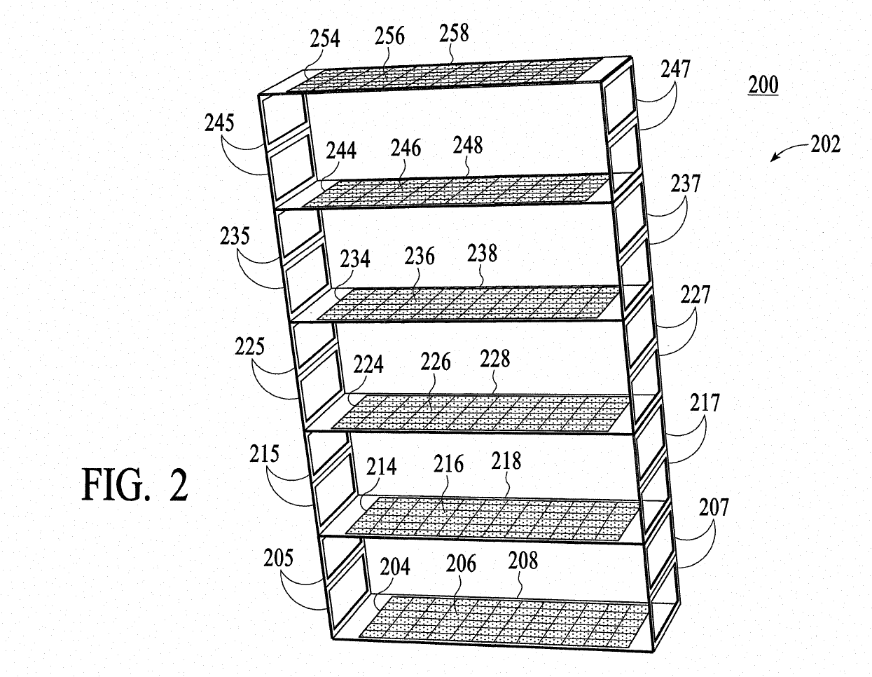

FIG. 2 illustrates an example auxiliary view 200 of an SPG module 202 in fully expanded and vertically-deployed and gravity-deployed form deployed by the force of gravity when anchored or hung or supported from it top (not shown), in accordance with teachings of the present disclosure. The SPG module 202 is illustrated to have six SPS building blocks (units) 204, 214, 224, 234, 244, and 254. 206, 208, 210, 212, and 214. The unit 204 includes an assembly 206 of partitioned rectangular bifacial solar cells within an in-laminate frame 208. Similarly, the units 214, 224, 234, 244, and 254 include assemblies 216, 226, 236, 246, and 256 of partitioned rectangular bifacial solar cells within in-laminate frames 218, 228, 238, 248, and 258 respectively. The units 204, 214, 224, 234, 244, and 254 are interconnected by the 205, 207, 215, 217, 225, 227, 235, 237, 245, 247 as shown.

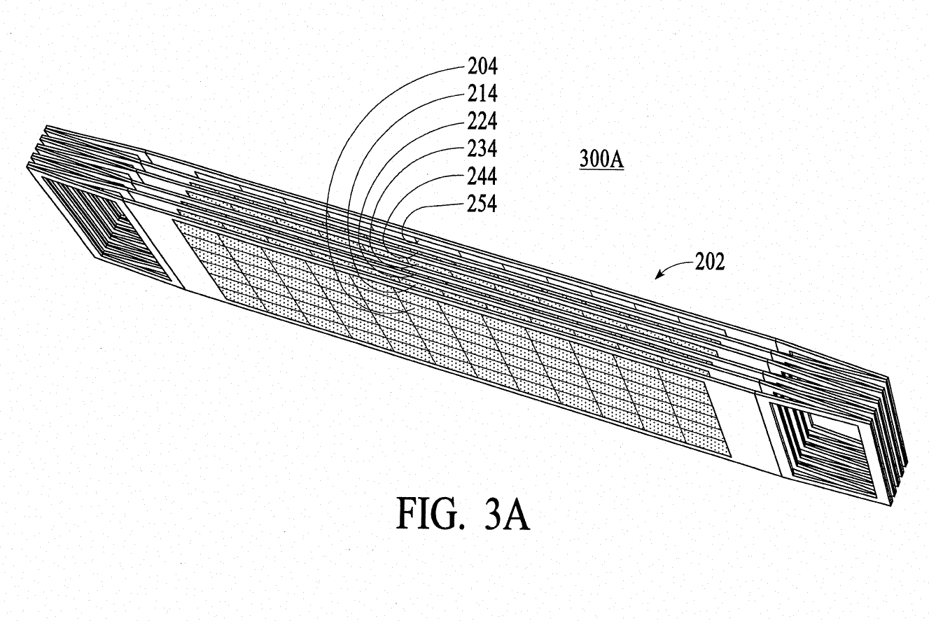

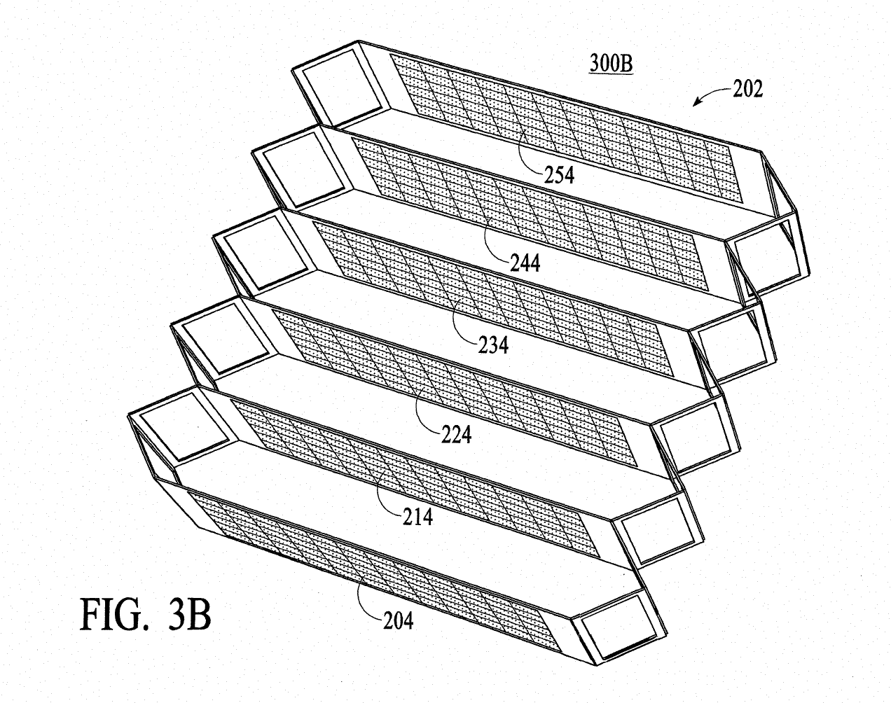

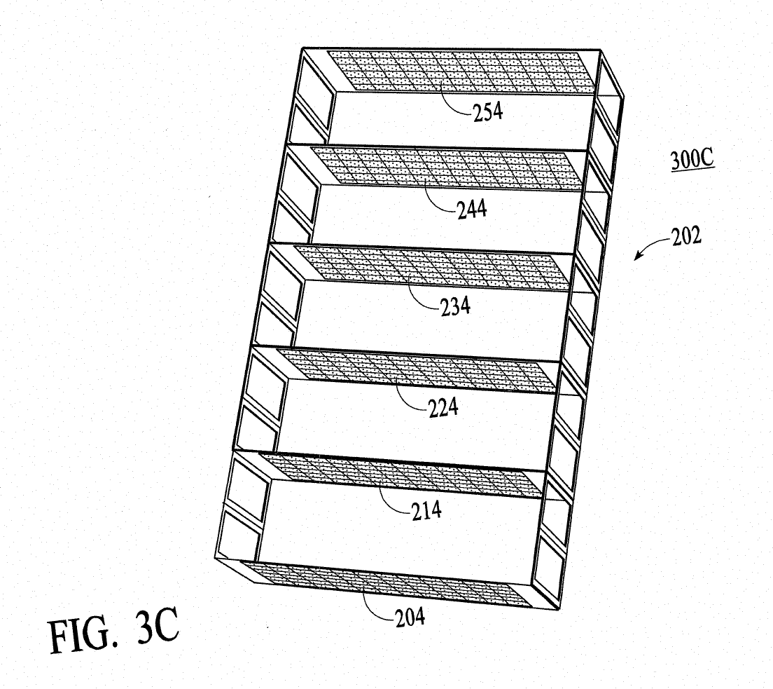

FIG. 3A illustrates an example view 300A of an SPG module 302 202 in a fully retracted form (not yet vertically deployed), according to the present disclosure. The SPG module 302 is illustrated to have six SPS building blocks (units) 304, 306, 308, 310, 312, and 314, 204, 214, 224, 234, 244, and 254. In other examples, there can be any number of plurality of SPS units depending on the application (for instance, between 2 and 100 SPS units within an SPG module). The number of SPS units may typically range from three to hundred in most applications.

FIG. 3B illustrates an example view 300B of the SPG module 322 202 of FIG. 2 comprising the SPS units (324, 326, 328, 330, 332, and 334 204, 214, 22, 234, 244, and 254) in a partially expanded or deployed form (but not shown as vertically-deployed or gravity-deployed in this figure) according to the present disclosure. The SPG module 322 is similar to the SPG module 302 of FIG. 3A.

FIG. 3C illustrates an example an example view 300C of the SPG module 202 of FIG. 2 comprising the SPS units (204, 214, 224, 234, 244, and 254) in a fully expanded or deployed form (but not shown as vertically-deployed or gravity-deployed in this figure) according to the present disclosure. The SPG module 342 is similar to the SPG module 302 of FIG. 3A and FIG. 3B.

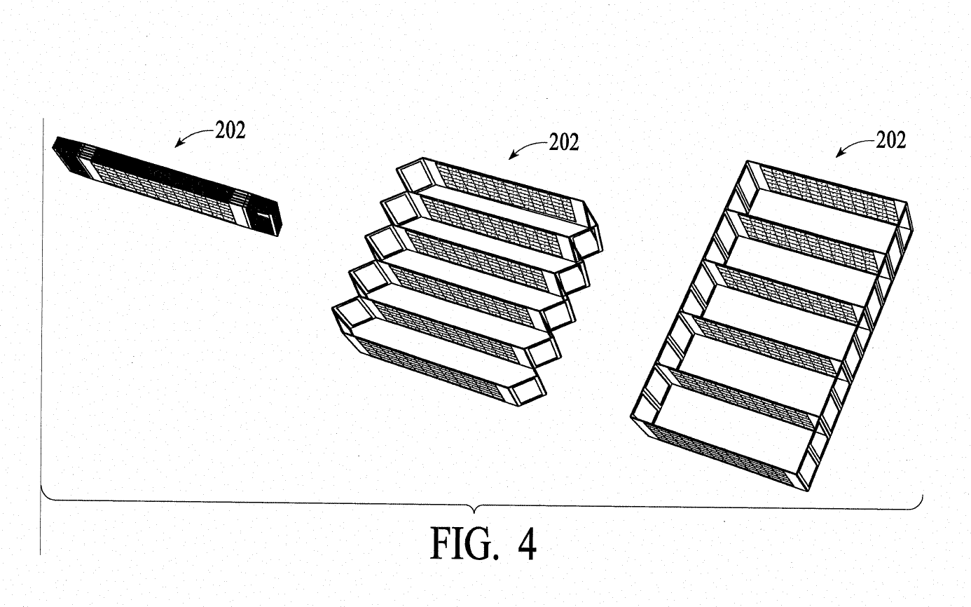

FIG. 4 illustrates an example view 400 of the SPG module 202 in a fully retracted, partially expanded, and fully expanded forms placed alongside each other.

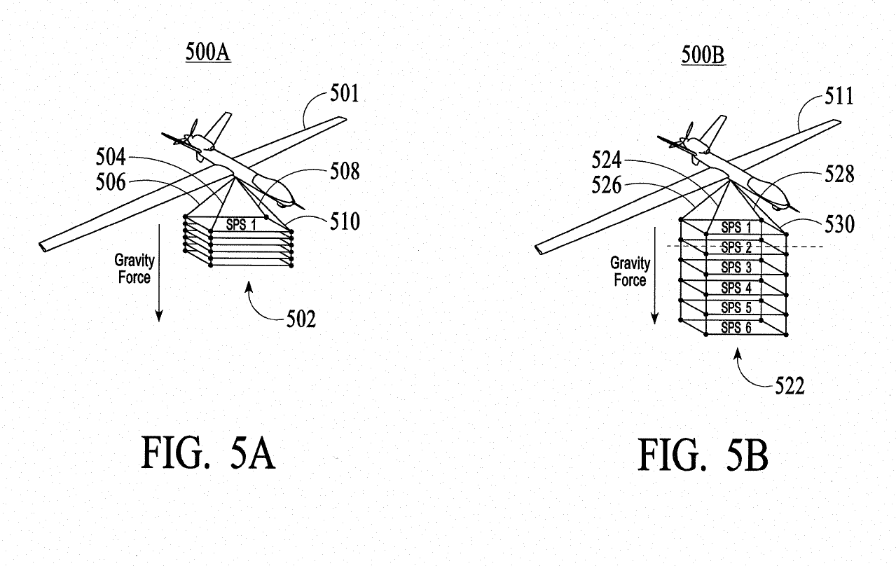

FIG. 5A illustrates an example application 500A of a module 502 in a fully retracted form anchored to an airborne drone 501, according to the present disclosure. The module 502 is shown to be anchored via anchoring connectors 504, 506, 508, and 510 (the anchoring, attachment, and support of the module from its topside can be done in many ways). In one example, there can be up to a total of four connector cords. Other examples may include more number of anchoring cords.

FIG. 5B illustrates an example application 500B of an SPG module 522 in a fully expanded (vertically deployed and gravity deployed) form anchored to an airborne drone 511, according to the present disclosure. The module 522 is shown to be anchored via anchoring connectors 524, 526, 528, and 530 (the anchoring, attachment, and support of the module from its topside can be done in many ways). The module 522 is shown to include the units SP1, SP2, SP3, SP4, SPS, and SP6 which can capture light on both the surfaces.

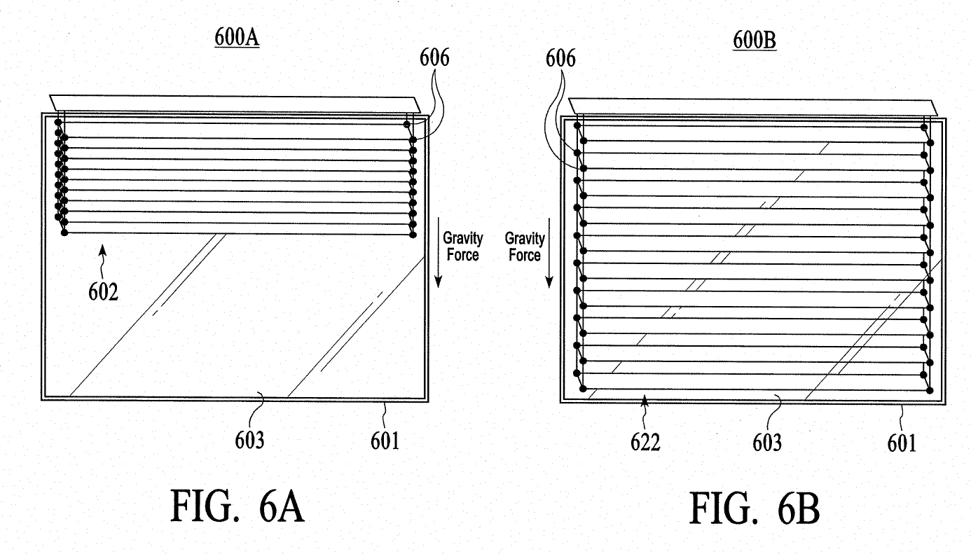

FIG. 6A illustrates an example application 600A of a vertically-supported module 602 in a fully retracted form used as a building window covering, according to the present disclosure. The module 602 can be anchored to a window frame 601 having a window glass 603. When retracted (compacted & stacked SPS units) the bifacial SPS units plane long axes are perpendicular (or nearly perpendicular) to the gravitational force, and the electromechanical or electro-structural connectors or cords (shown as a set 606) pull up the slatted bifacial module for compaction.

FIG. 6B illustrates an example application 600B of a module 622 602 in a fully expanded form used as a building window covering, according to the present disclosure. The module 602 can be anchored to the window frame 601 having a window glass 633. When expanded and vertically deployed along the force of gravity, the bifacial SPS units plane long axes are perpendicular (or nearly perpendicular) to the gravitational force, and the electromechanical or electro-structural connectors or cords (shown as a set 606) are extended for full vertical deployment and power generation. The bifacial SPS units (SP1, SP2, SP3, SP4, SP5, SP6, SP7, SP8, SP9, and SP10) can also have optional tilt adjustment.

As can be seen from FIGS. 6A and 6B, with optional SPS tilt adjustment feature, the tilt angles of all SPS units preferably remain parallel to one another for all SPS plane tilt angles with respect to the force of gravity.

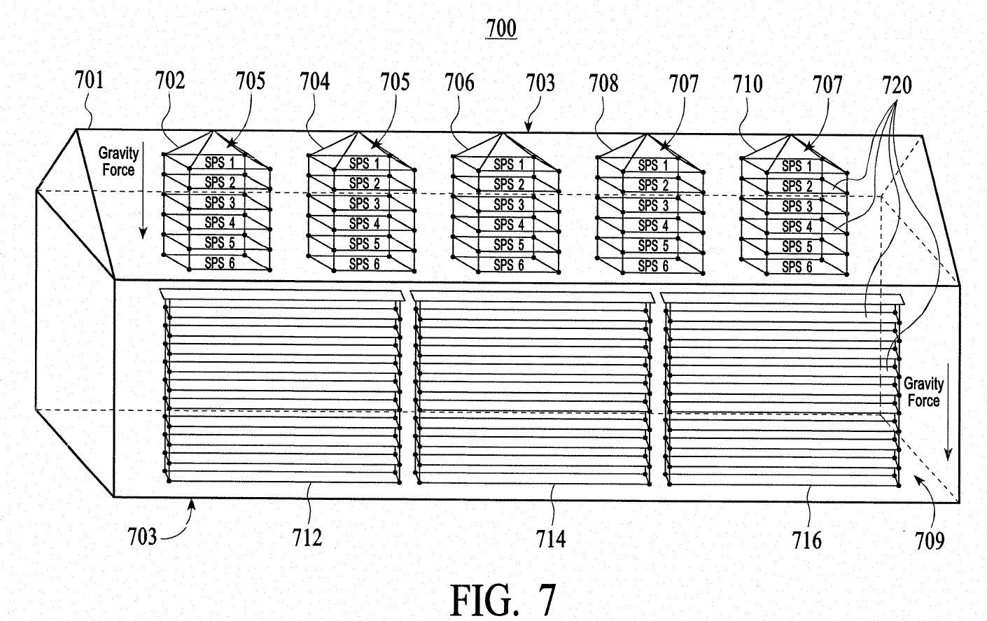

FIG. 7 illustrates an example application 700 of an SPG modules 702, 704, 706, 708, 710, 712, 714, and 716 shown in fully expanded vertically-deployed (gravity-deployed) forms used for generating electricity in a greenhouse structure 701, according to the present disclosure. The bifacial SPS units (shown collectively as 720) capture light from both bifacial SPS faces. As shown, the green house floor area can be made fully available for plants while allowing for sufficient sunlight to come through for plant yield. As shown, the modules 702, 704, 708, and 710 can be hanged from a ceiling 703, whereas modules 712, 714, and 716 can be hanging on the wall 709.

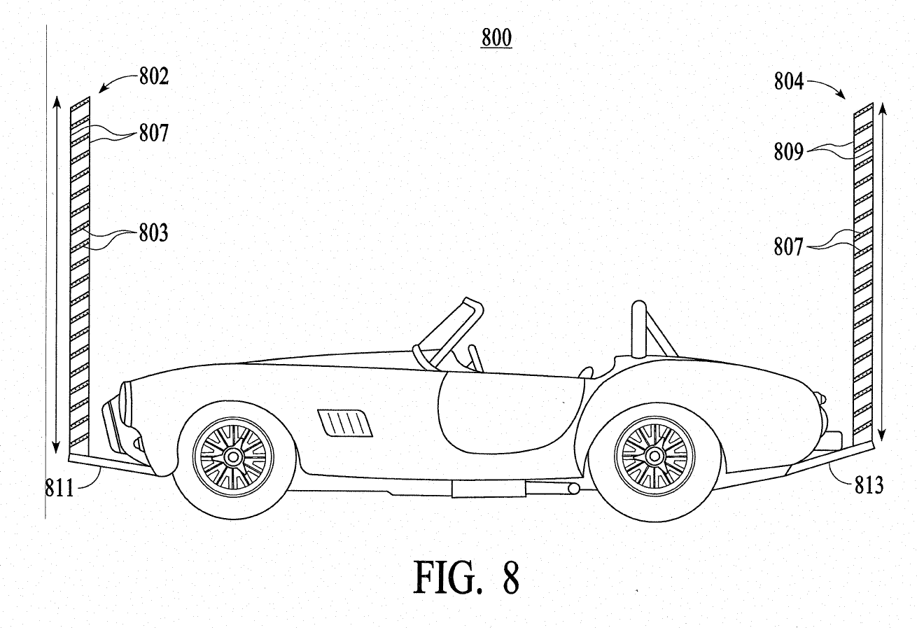

FIG. 8 illustrates an example 800 of a side view of an electric car (example shows Tesla Model S having dimensions 196.0″L×77.3″W×57″H (4.98 m×1.96 m×1.45 m)) having with mounted SPG modules 802 and 804 in a fully expanded vertically-deployed form for on-board electric vehicle charging, according to the present disclosure. The modules 802 and 804 are vertically deployable and retractable and can be mounted on the front side and/or the rear side of the car respectively using the bottom module supports 811 and 813 respectively. As can be seen the SPS units (collectively shown as 803 and 805) are expanded fully or at least partially expanded via the connectors (collectively shown as 807 and 809) for power generation. Either one module or both modules can be mounted and used as on-board electric vehicle (EV) chargers. The number of SPS units can be approximately 10 to 50. Moreover, the length of SPS Building Blocks (unit) may be approximately equal to the width of the car (or a fraction of the width of the car). Also, the width of SPS Building Blocks (units) may be approximately equal to the width of a single solar cell. In most applications the active electricity-generating width of a rectangular SPS building block is the same as the width of a standard crystalline silicon solar cell (which may be about 16 cm); it may also be a smaller fraction of the width of a solar cell. An SPS tilt angle control may also be implemented for this application. In one example, the modules 802 and 804 can be fully expanded up to a height of 1.5 meters to 2.5 meters.

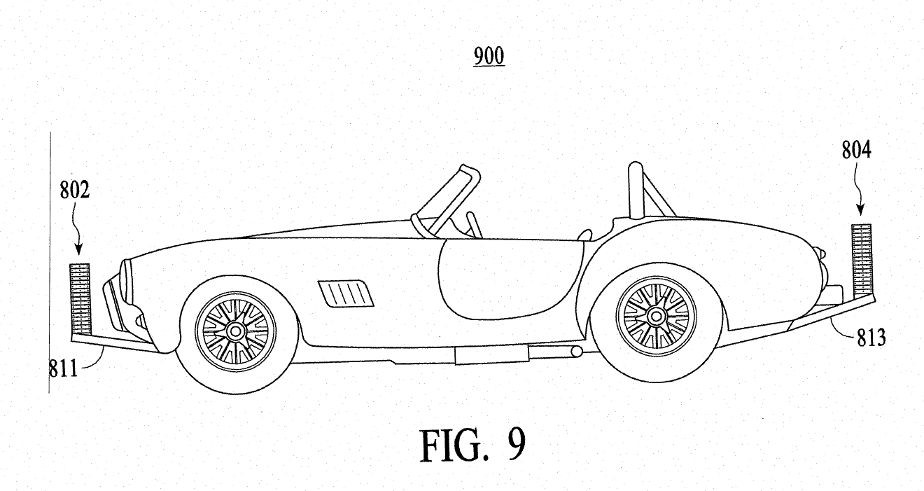

FIG. 9 illustrates an example 900 of a side view of an electric car of FIG. 8 (example shown for Tesla Model S) having SPG modules 902 802 and 904 804 in a fully retracted form for on-board electric vehicle (EV) charging, according to the present disclosure. The modules 902 802 and 904 804 are vertically deployable and retractable and can be mounted on the front side and/or the rear side of the car using the bottom module supports 811 and 813 respectively. Either one module or both modules can be mounted. The number of SPS units can be approximately 10 to 50. Moreover, the length of SPS Building Blocks (unit) may be approximately equal to the width of the car (or a fraction of the width of the car). Again, in most applications the active electricity-generating width of a rectangular SPS building block is the same as the width of a standard crystalline silicon solar cell (which may be about 16 cm). An SPS tilt angle control may also be implemented for this application for when the SPG modules are vertically expanded and deployed for electricity generation.

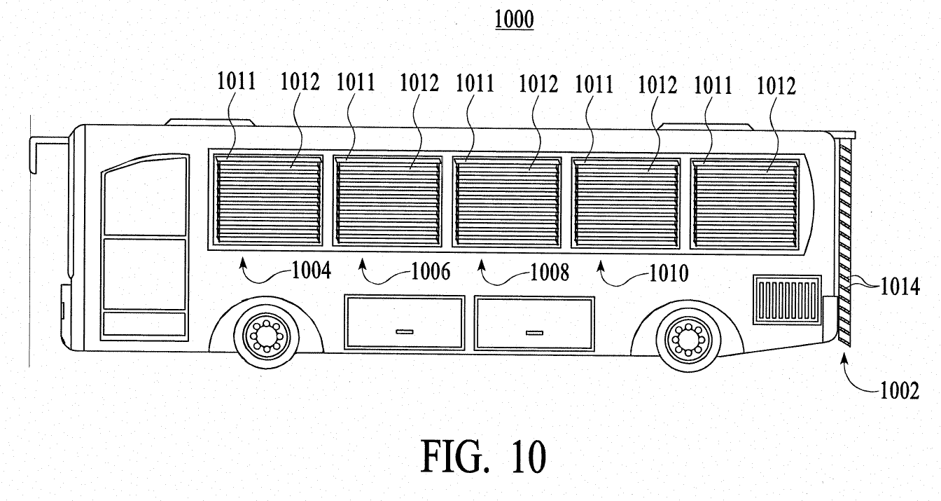

FIG. 10 illustrates an example 1000 of a side view of an electric bus with vertically deployable SPG module 1002 comprising bifacial SPS units (collectively shown as 1014) in a fully expanded form mounted on the read side of the bus for on-board electric bus charging, according to the present disclosure. The bus windows may also be optionally covered using the plurality of gravity-oriented and vertically-deployed SPG modules 1004, 1006, 1008, and 1010 comprising the SPS units (collectively shown as 1012). There is a retraction and expansion anchoring mechanism at the top of each module as shown by 1011. The length of SPS units may be approximately equal to the width of the bus or a fraction thereof. In most applications the active electricity-generating width of a rectangular SPS building block is the same as the width of a standard crystalline silicon solar cell (which may be about 16 cm); it may also be a smaller fraction of the width of a solar cell. SPS tilt angle control may also be implemented for enhanced electricity generation.

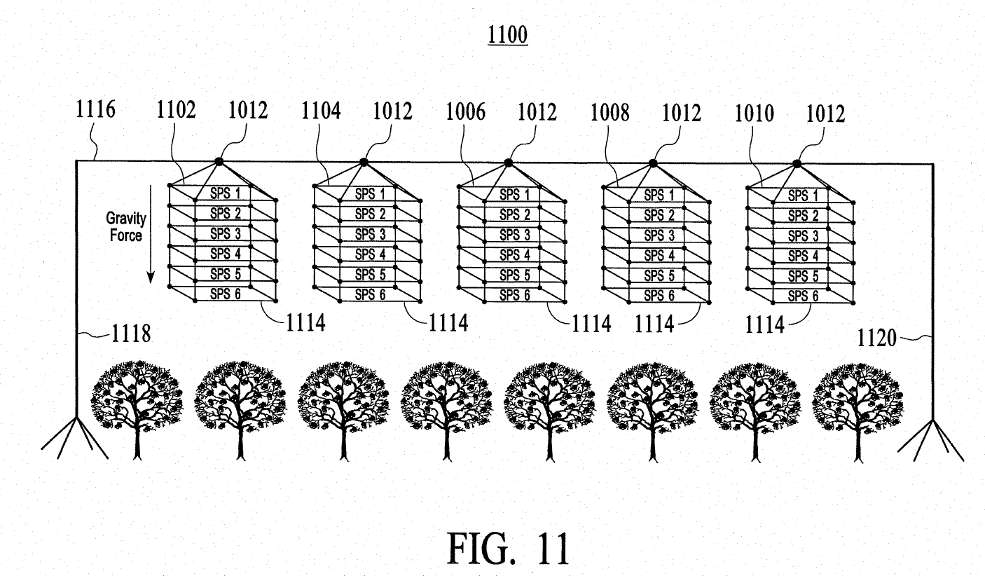

FIG. 11 illustrates an example application 1100 of SPG modules 1102, 1104, 1106, 1108, 1010 comprising bi-facial SPS units (collectively shown as 1114) in a fully expanded form vertically deployed (gravity oriented) by hanging over an outdoor fields, according to the present disclosure. Electromechanical or electro structural connectors shown collectively as 1012 may be used for anchoring gravity-oriented modules from their topsides to a lateral cord or beam 1116 connected between ground-mounted support posts or columns 1118 and 1120. The posts 1118 and 1120 may also provide electrical connections to the power leads (not shown) of the SPG modules. The posts 1118 and 1120 attached to the ground supporting the lateral cord 1116 may be telecom or electric power or street light poles.

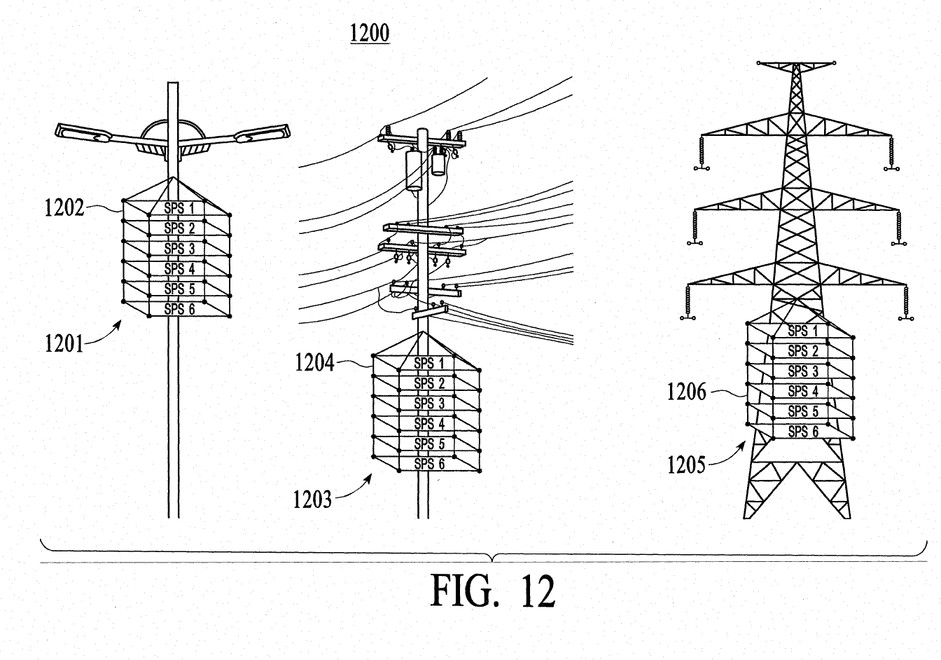

FIG. 12 illustrates an example application 1200 of gravity-oriented vertically-deployed SPG modules 1202, 1204, and 1206 in a fully expanded or deployed form by hanging from a street light pole 1201, a telecom and/or low-voltage power pole 1203, a high voltage power transmission tower 1205 respectively, according to the present disclosure. Other similar embodiments can also include telecommunication cell towers.

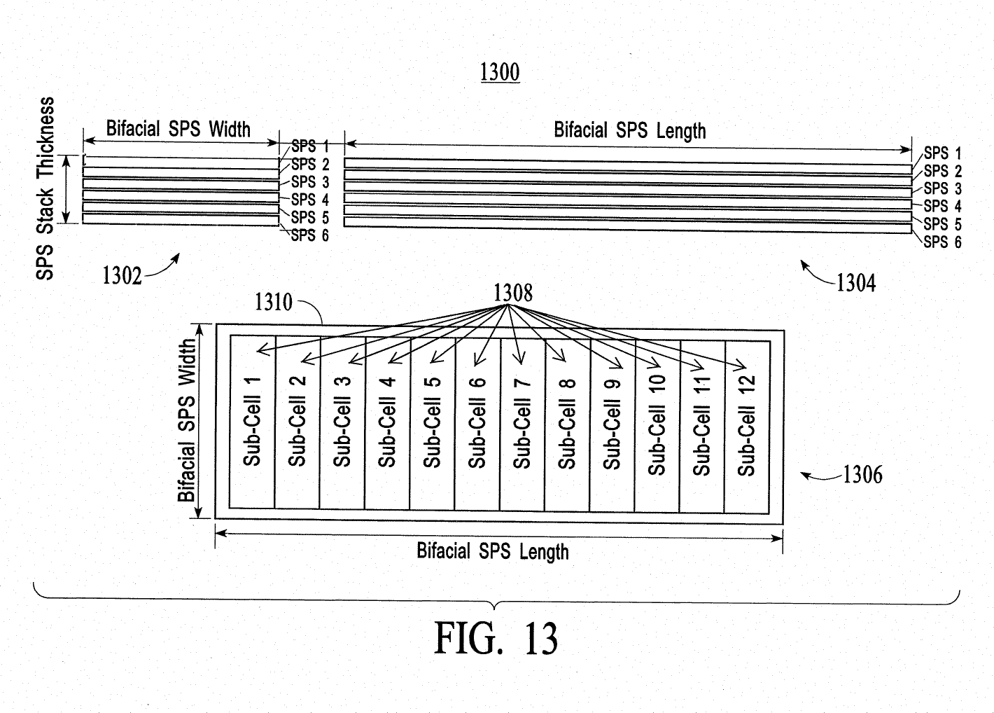

FIGS. 13 to 15 various examples of an ultra-lightweight sliding-mode architecture for SPG modules with a high surface compaction ratio. The example shows six SPS units stacked together but the number of SPS units can be anywhere typically from three to a hundred or even unlimited.

FIG. 13 illustrates an example 1300 of various views of a sliding-mode architecture for an ultra-lightweight RDP-SPG module (example module shown with 6 SPS units) with a high compaction ratio shown in a fully retracted and compacted form, according to the present disclosure. Illustrated in FIG. 13 are a short-side view 1302 and a long-side view 1304 of stacked SPS units in the SPG module in a retracted and compacted form. Also shown is a plan view 1306 of the top SPS unit comprising a total of twelve sub-cells (shown collectively as 1308) within an in-laminate frame 1308 (the number of sub-cells in each SPS unit may be different than 12, depending on the design requirements and the multi-modal MPPT chip specifications). The sub-cells 1308 are overlapping (they may also be co-planar instead of overlapping) and connected in an electrical series within each SPS unit. Each SPS unit in 1302 and 1304 is assumed to comprise twelve series sub-cells. The number of sub-cell in one unit may also be smaller or larger than 12 (for instance, the number may be between 6 and 10's of sub-cells; most commonly the number of sub-cells within each SPS unit is between 8 and 20). Adjacent bifacial SPS building blocks (units) are electromechanically or electro-structurally attached together using sliding sides with rails & guides with end stops on their shorter sides (details not shown in this figures). In some examples, the in-laminate frame 1308 may be made of a fiber-reinforced composite polymer e.g., ULTRAMID or ULTRADUR.

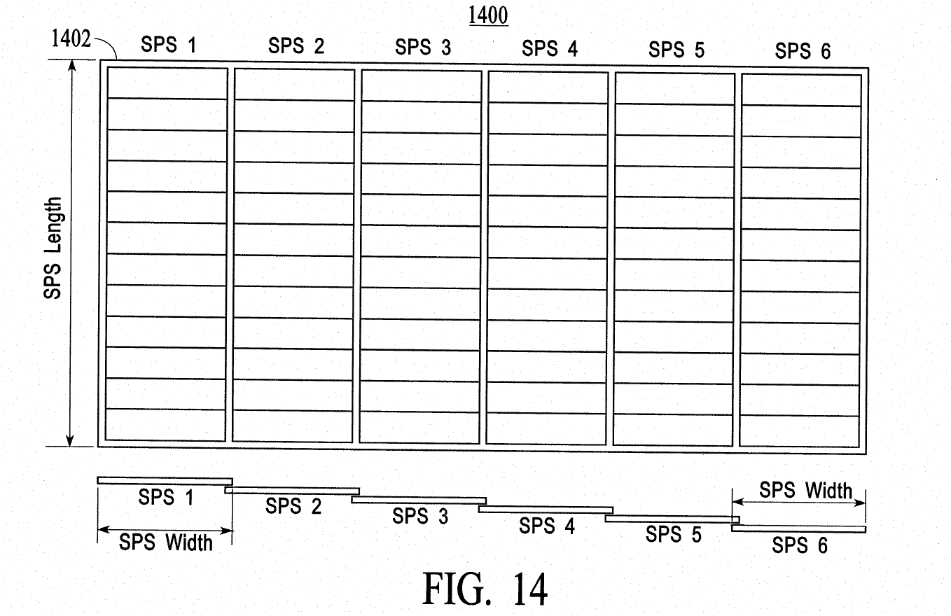

FIG. 14 illustrates an example 1400 of a plan view and an example side view 1404 of an ultra-lightweight sliding-design RDP-SPG module 1402 with a high surface compaction ratio shown in a fully expanded and deployed form for power generation, according to the present disclosure. The module 1402 deployed as shown may be considered as in electricity-generation state. The SPS units can be interconnected using edge rail guides on the shorter sides (not shown in this figure).

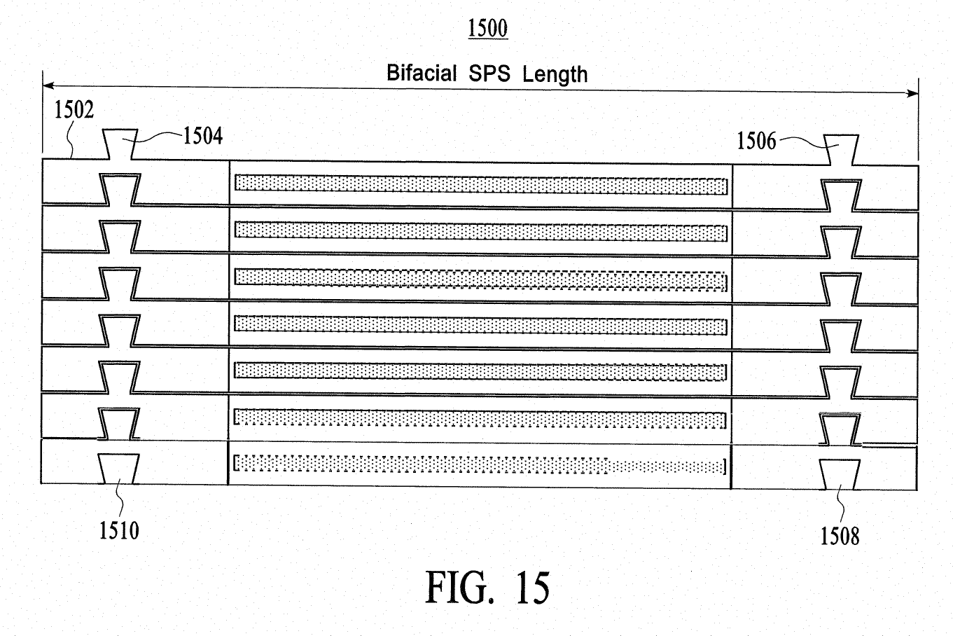

FIG. 15 illustrates an example 1500 of cross-sectional side view 1502 of an ultra-lightweight RDP-SPG module with a high surface compaction ratio showing the edge guide rails on the shorter sides of the SPS building blocks, according to the present disclosure. More specifically, the cross-sectional view illustrates FIG. 15 illustrates the edge guide rails 1504 and 1506 on the shorter sides of the SPS units. Each SPS laminate may be made of ETFE-EVA-Sub Cells-EVA-ETFE (or an equivalent laminate material stack) with an in-laminate frame used as the main support structure. As can be seen, there are SPS guide cavities 1508 and 1510 on the shorter sides. The in-laminate SPS frames and edge guides & rails may be made of injection-molded composite polymers.

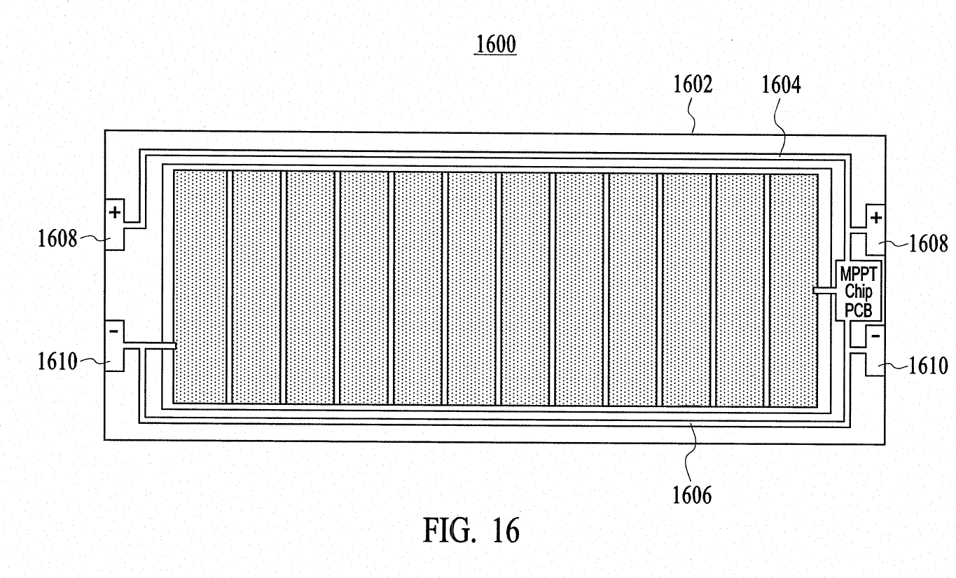

FIG. 16 illustrates a first example design layout 1600 of an SPS building block 1602 including a plurality of sub-cells, according to the present disclosure. The SPS unit 1602 features a design of in-laminate-frame-supported ribbons and leads without any additional end-to-end connectors. SPS unit 1602 is illustrated to include 12 series-connected overlapping sub-cells with (SPS positive and negative electrical pads on both sides). As shown, the SPS unit 1602 comprises an SPS positive rail copper ribbon 1604 and an SPS negative rail copper ribbon 1606. The copper ribbon runners 1604, 1606 and the positive leads 1608 and negative leads 1610 of the SPS building block 1602 are accessible on both of its shorter sides of the SPS building block and on both front and back sides of the in-laminate composite frame 1610 (the details of intra-SPS electrical interconnections including the super-cell to MPPT chip connections and copper ribbon to super-cell and MPPT chip are not shown). Copper Ribbons 1604 and 1606 are attached to and supported by the in-laminate frame 1610. Furthermore negative SPS power output is available on both sides.

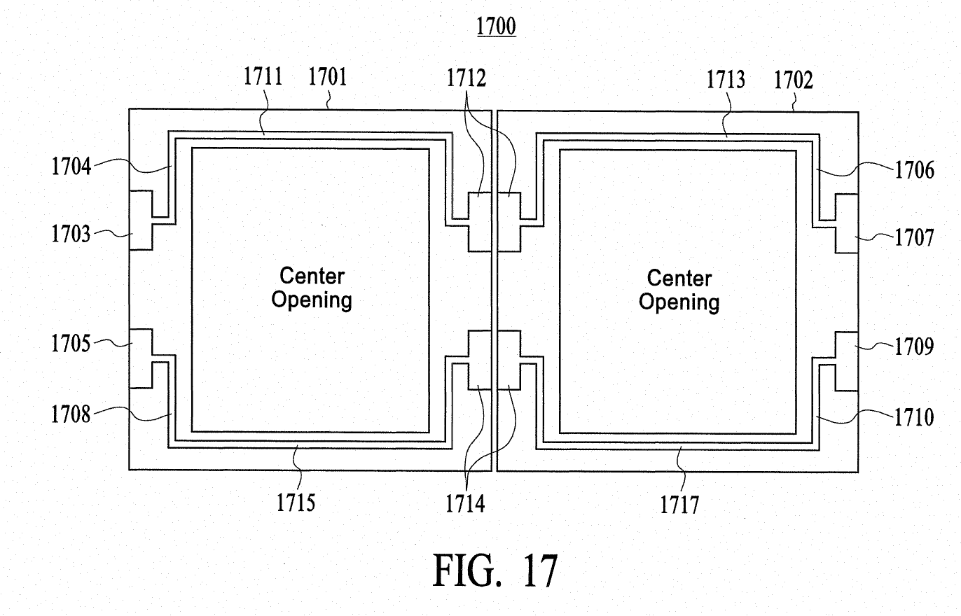

FIG. 17 illustrates a first example 1700 of two frame shaped electromechanical or electro-structural connectors 1701 and 1702 for an SPG module (not shown) having the SPS units of FIG. 16, according to the present disclosure. In particular, example 1700 illustrates a first example of a design layout of a connector frame supported ribbons and leads without any additional end-to-end long-range connectors. The connector-frame-supported copper ribbon runners with leads (e.g., electrically conductive hinge landing pads) on the opposite ends of a pair of adjacent connector frames (the copper ribbons and hinge landing pads are preferably only on one side of the connector frames). As can be seen 1704 and 1706 are the top half planes of the hinge pads and the copper ribbons Similarly 1708 and 1710 are the bottom half planes of the hinge pads and the copper ribbons. The top conductive hinge pads 1712 and the bottom conductive hinge pads 1714 are for connecting adjacent SPS in-laminate frames. The 1704, 1706, 1708, and 1710 provide connections to the SPS leads. The hinge pads 1714 and 1716. 1703, 1705, 1707, 1709 are electrically conductive hinge pads which may also be connected to an adjacent SPS unit (hinges and SPS unit not shown). This design may use only half of the hinge pads and conductor (copper) ribbons shown. For most SPS interconnections the ribbons and hinges on only one half-plane of the connector-frame is sufficient. All conductor pads and copper runners may be on only one face of the connector frames. In general open connector frames are much preferred over solid connector plates because of reduced weight and minimal sunlight and daylight blockage of the RDP-SPG module. The top and bottom conductive hinge pads 1712 and 1714 are for electromechanically connecting ribbons on a pair of adjacent connector frames (hinge or spring not shown).

Each of the connector frames 1710 1701 and 1702 as explained above has a center opening for reducing the overall weight of the SPG module (preferably frame-shaped connectors instead of plate connectors for reduced weight). This layout also has an inter-SPS connector copper ribbons 1711, 1713, 1715, and 1717 overlaid on inter-SPS connector frames (copper ribbons on only one side of the connector frame).

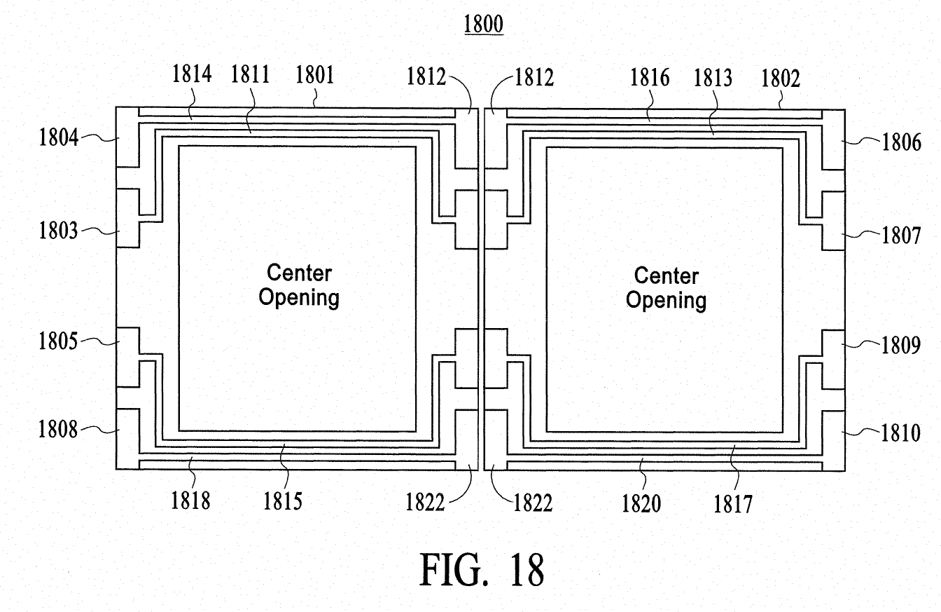

FIG. 18 illustrates a first example 1800 of two frame shaped electromechanical or electro-structural connectors 1801 and 1802 for an SPG module (not shown) according to the present disclosure. In particular, example 1800 illustrates a first example of a design layout of a connector frame supported ribbons and leads with additional end-to-end long-range connectors. The connector-frame-supported copper ribbon runners with leads (e.g., electrically conductive hinge landing pads) on the opposite ends of a pair of adjacent connector frames (the copper ribbons and hinge landing pads are preferably only on one side of the connector frames). As can be seen there are additional hinge pads 1804, 1806, in the corners of the frame 1801 Similarly, there are additional hinge pads 1808, 1810 in the corners of the frame 1802. There are copper ribbons 1811, 1813, 1815, and 1817 on the inner side of the in-laminate. There are additional copper ribbons 1814, 1816, 1818, and 1820. The four electrically conductive hinge pads 1803, 1804, 1805, and 1808 of the frame 1801 may also be connected to the adjacent SPS unit (the adjacent SPS unit and hinges not shown) Similarly, the four electrically conductive hinge pads 1806, 1807, 1809, and 1810 of the frame 1802 may also be connected to the adjacent SPS unit (the adjacent SPS unit and hinges not shown). Top hinge pads pair 1812 and the bottom hinge pad pair 1822 of conductive hinges electromechanically connect ribbons on pair of adjacent connector frames as shown. All conductor pads and runners on one face of the connector frames. This design provides additional conductor ribbons for long-range interconnections. This design may use only half of the hinge pads and conductor (copper) ribbons shown. For most SPS interconnections the ribbons and hinges on only one half-plane of the connector-frame is sufficient. Additionally, each of the connector frames 1801 and 1802 as explained above has a center opening for reducing the overall weight of the SPG module (preferably frame-shaped connectors instead of plate connectors for reduced weight).

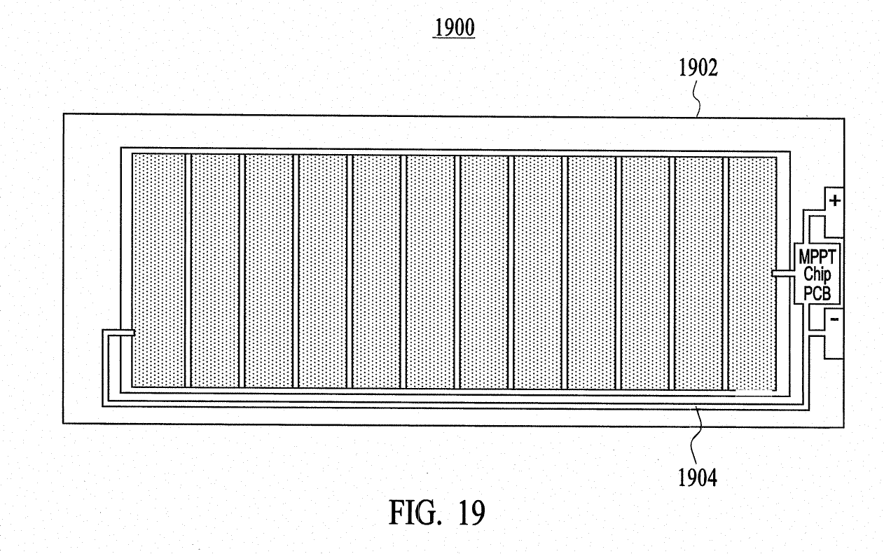

FIG. 19 illustrates a second example design layout 1900 of an SPS laminate building block including a plurality of electrically connected partitioned sub-cells nested within an in-laminate frame and embedded within the laminate, providing both the positive and negative electrical power leads on only one of the shorter ends of the SPS laminate building block, according to the present disclosure. Specifically, FIG. 19 illustrates a design layout 1900 of an SPS building block 1902 including a plurality of sub-cells, according to the present disclosure. The SPS unit 1902 features a design of in-laminate-frame-supported ribbons and leads without any additional connectors. SPS unit 1902 is illustrated to include 12 series-connected overlapping sub-cells with (positive and negative pads on both sides). As shown, the SPS unit 1902 comprises an SPS copper ribbon runner 1904 and the positive and negative leads of the SPS building block 1902 accessible on both shorter sides of the SPS building block and on both front and back sides of the in-laminate composite frame (the details of intra-SPS electrical interconnections including the super-cell to MPPT chip connections and copper ribbon to super-cell and MPPT chip not shown).

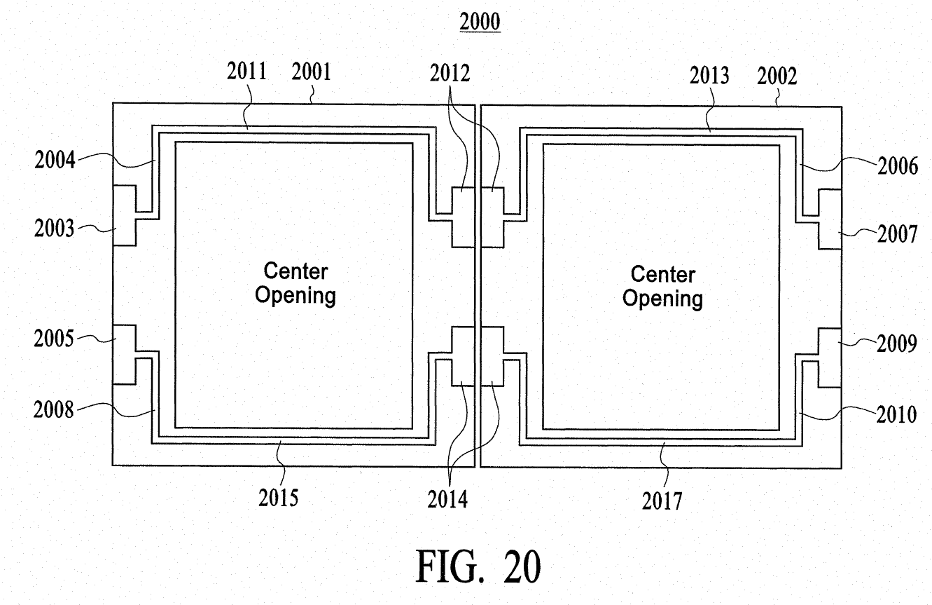

FIG. 20 illustrates an example 2000 of electro-structural (or electro-mechanical) connector, comprising a retractable & expandable structural connector part also having electrical interconnections (such as copper ribbons) for connections of the electrical power leads between any two adjacent SPS building blocks of FIG. 19, according to the present disclosure. This figure illustrates an example 2000 of two frame shaped electro-structural connectors 2001 and 2002 for an SPG module (not shown) according to the present disclosure. The design layout 2000 is similar to the design layout 1700. Therefore, a person skilled in the art may refer to the description of FIG. 17 for FIG. 20. The numerals 2003, 2004, 2005, 2006, 2007, 2008, 2009, 2010, 2011, 2012, 2014, 2015, and 2017 point to the same parts of the connectors 2001 and 2002 as their counterparts with respect to FIG. 17.

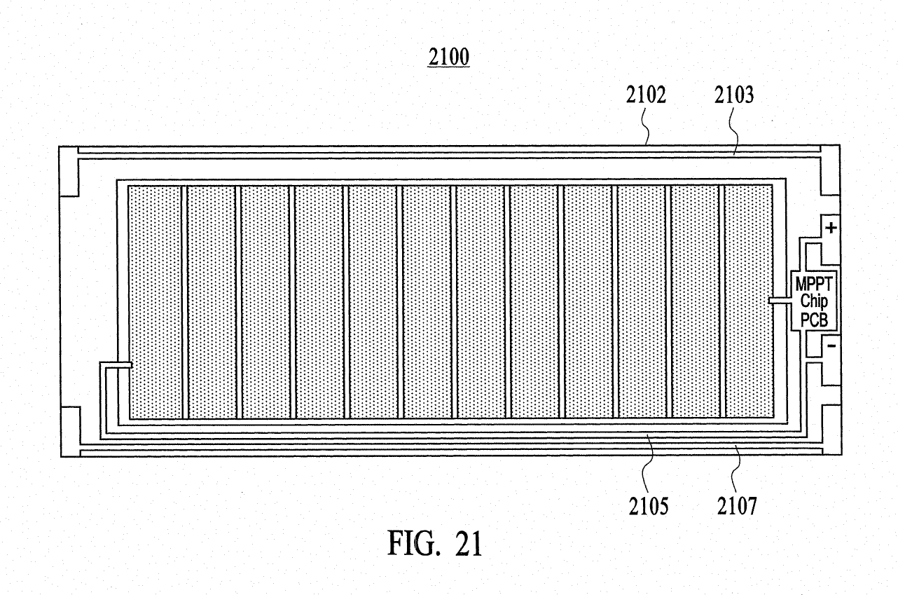

FIG. 21 illustrates a third example design layout 2100 of an SPS laminate building block including a plurality of electrically connected partitioned sub-cells nested within an in-laminate frame and embedded within the laminate, providing both the positive and negative electrical power leads only on one of the shorter ends of the SPS laminate building block, and further providing additional end-to-end long-range connectors and additional connector leads, according to the present disclosure. This figure illustrates an example design layout 2100 of an in-laminate frame with additional end-to-end connectors for an SPS building block 2102 including a plurality of overlapping sub-cells, according to the present disclosure. The frame-supported copper ribbon runners and the positive and negative leads of the SPS building block on both shorter sides of the SPS unit and on both front and back sides of the in-laminate composite frame (the details of intra-SPS electrical interconnections including the super-cell to MPPT chip connections and copper ribbon to super-cell and MPPT chip not shown; SPS size and dimensions not shown to relative scale).

This design version includes additional pairs 2103 and 2107 of end-to-end copper ribbon connectors on both the opposite sides (front side and back side) of the in-laminate SPS composite frame 2102.

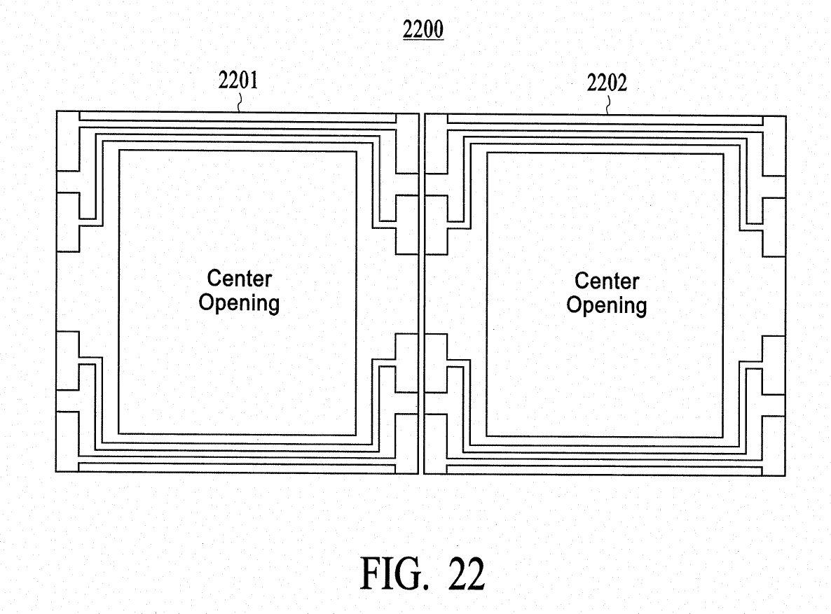

FIG. 22 illustrates an example 2200 of electro-structural (or electro-mechanical) connector, comprising a retractable & expandable structural connector part also having electrical interconnections (such as copper ribbons) for connections of the electrical power leads between any two adjacent SPS building blocks of FIG. 21, and further providing additional end-to-end long-range connectors and additional connector leads, according to the present disclosure (design is similar to FIG. 18. This figure shows an example 2200 of two frame shaped connectors 2201 and 2202 for an SPG module (not shown) according to the present disclosure. The design layout 220 is similar to the design layout 1800. Therefore, one skilled in the art may refer to the description of FIG. 18 for a description of FIG. 22. Additionally, each of the connector frames 2201 and 2202 as explained above has a center opening for reducing the overall weight of the SPG module (preferably frame-shaped connectors instead of plate connectors for reduced weight).

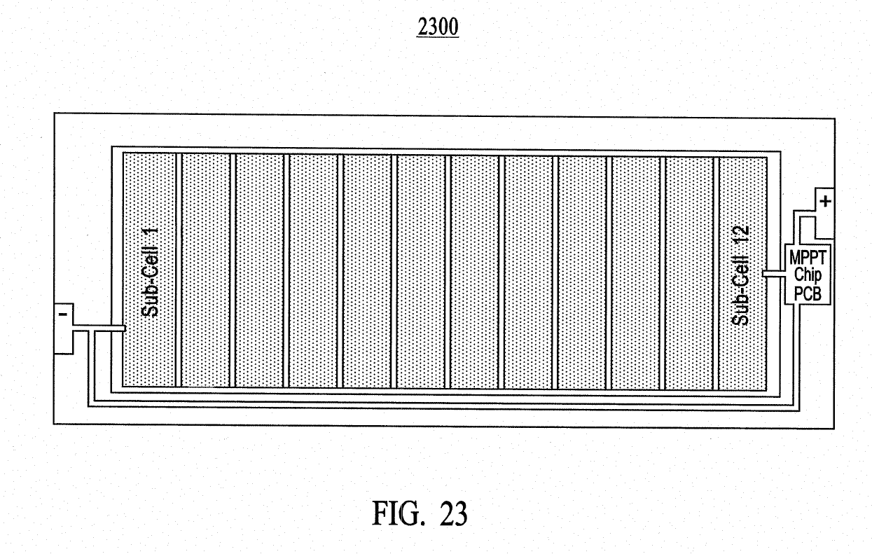

FIG. 23 illustrates a fourth example design layout 2300 of an SPS laminate building block including a plurality of electrically connected partitioned sub-cells nested within an in-laminate frame and embedded within the laminate, providing the positive electrical power lead on one of the shorter ends and the negative electrical power lead on the opposite shorter end of the SPS laminate building block (positive on one end and negative on the opposite end), according to the present disclosure. This is a representative SPS design of In-Laminate-Frame-Supported Ribbons and Leads (Design Option 3), without additional connectors. The example shows an SPS building block with 12 series-connected overlapping sub-cells. This figure illustrates an example design layout 2300 of an SPS building block 2302 including a plurality of sub-cells, according to the present disclosure. The design layout 2300 is similar to the design layout 1900. Therefore, one skilled in the art may refer to the description of FIG. 19 for a description of FIG. 23. More specifically, this design example shows SPS-long frame-supported copper ribbon runners, with positive and negative leads of the SPS building block accessible on both shorter sides of the SPS building block and on both front and back sides of the in-laminate composite frame. The details of intra-SPS electrical interconnections including the super-cell to MPPT chip connections and copper ribbon to super-cell and MPPT chip are not shown.

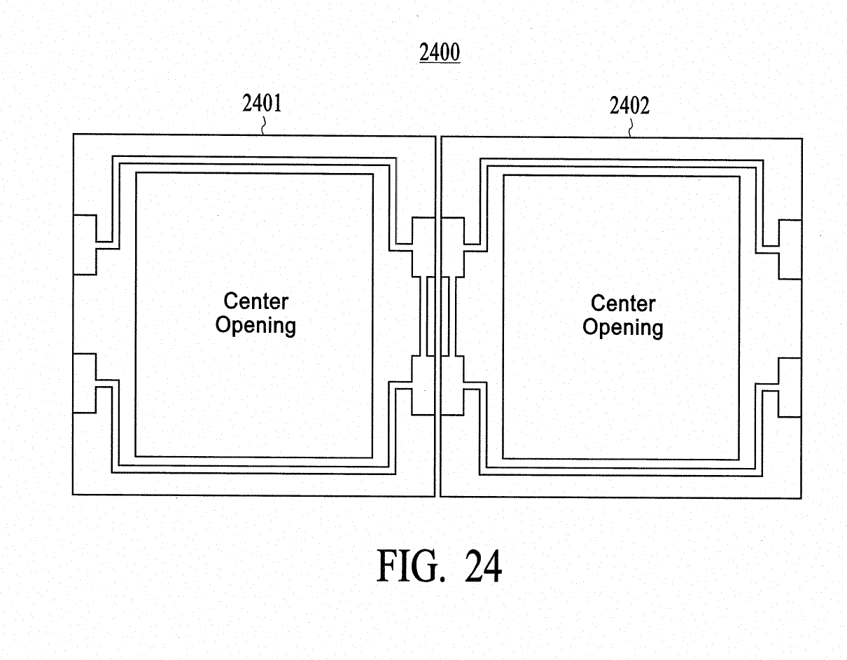

FIG. 24 illustrates an example 2400 of electro-structural (or electro-mechanical) connector, comprising a retractable & expandable structural connector part also having electrical interconnections (such as copper ribbons) for connections of the electrical power leads between any two adjacent SPS building blocks of FIG. 23, according to the present disclosure. This figure illustrates an example 2400 of two frame shaped connectors 2401 and 2402 for an SPG module (not shown) according to the present disclosure. The design layout 2400 is similar to the design layout 1700. Therefore, a person skilled in the art may refer to the description of FIG. 17 for FIG. 24. Additionally, each of the connector frames 2401 and 2402 as explained above has a center opening for reducing the overall weight of the SPG module (preferably frame-shaped connectors instead of plate connectors for reduced weight).

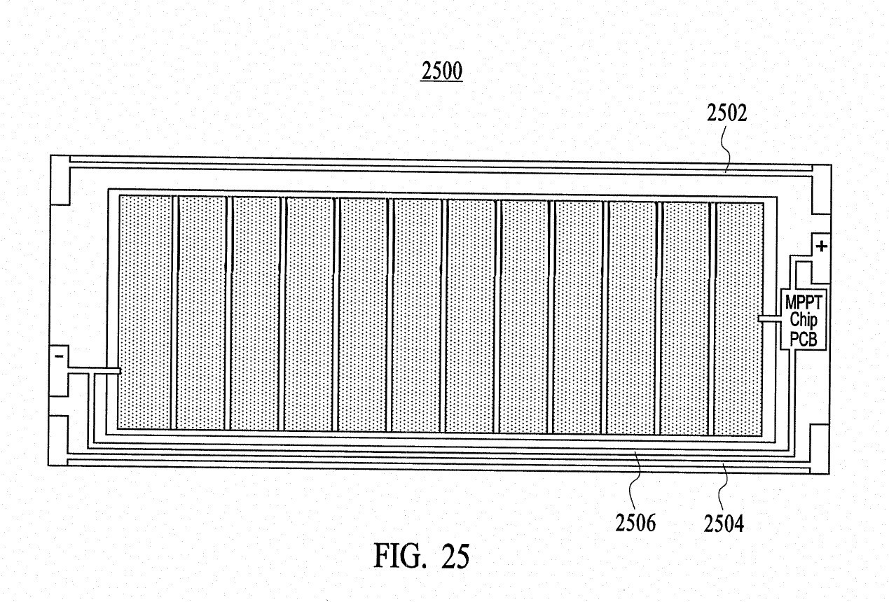

FIG. 25 illustrates a fifth example 2500 of an SPS laminate building block including a plurality of electrically connected partitioned sub-cells nested within an in-laminate frame and embedded within the laminate, providing the positive electrical power lead on one of the shorter ends and the negative electrical power lead on the opposite shorter end of the SPS laminate building block, and further providing additional end-to-end long-range connectors and additional connector leads, according to the present disclosure. This figure illustrates an example design layout 2500 of an in-laminate frame with additional connectors for an SPS building block 2502 including a plurality of overlapping sub-cells, according to the present disclosure. The design layout 2500 is similar to the design layout 2100. Therefore, a person skilled in the art may refer to the description of FIG. 21 for FIG. 25. This representative design includes the frame-supported copper ribbon runners (2502 and the positive and negative leads of the SPS building block on both shorter sides of the SPS unit and on both front and back sides of the in-laminate composite frame. The details of intra-SPS electrical interconnections including the super-cell to MPPT chip connections and copper ribbon to super-cell and MPPT chip not shown.

This design version includes additional pairs of end-to-end copper ribbon connectors on both the opposite sides (front side and back side) of the in-laminate SPS composite frame. These additional connectors provide full capability for interconnections of the SPS building block units in an RDP-SPG module in any one of all-series, hybrid parallel-series, or all-parallel configurations and provide accessible power leads on all corners of the RDP-SPG module

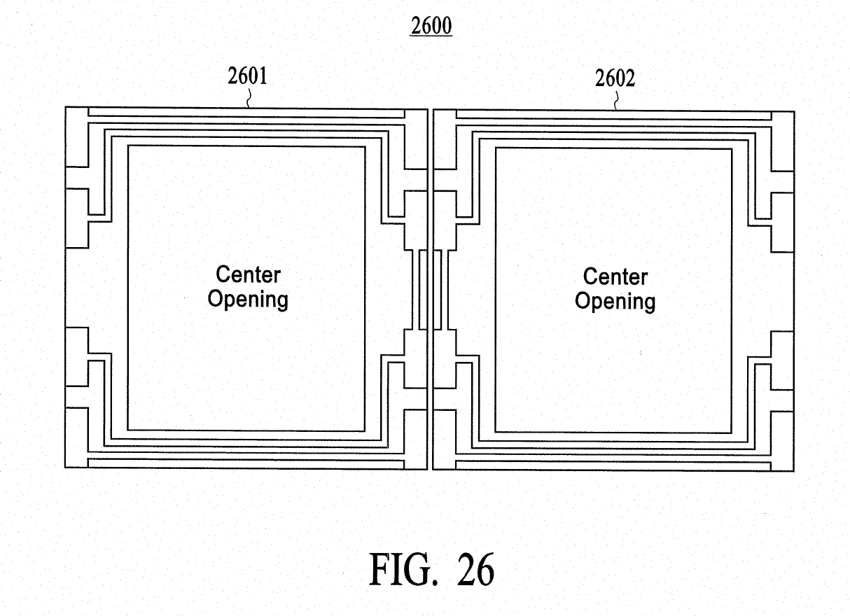

FIG. 26 illustrates an example 2600 of electro-structural (or electro-mechanical) connector, comprising a retractable & expandable structural connector part also having electrical interconnections (such as copper ribbons) for connections of the electrical power leads between any two adjacent SPS building blocks of FIG. 23, and further providing additional end-to-end long-range connectors and additional connector leads, according to the present disclosure. This figure illustrates an example design layout 2600 of a two frame shaped connectors 2601 and 2602 for an SPG module (not shown), according to the present disclosure. The design layout 2600 is similar to the design layout 1900. Therefore, a person skilled in the art may refer to the description of FIG. 19 for FIG. 26. One way in which it differs from the design layout of FIG. 19 is that it does not include any additional conductor ribbons for long-range interconnections. Additionally, each of the connector frames 2601 and 2602 as explained above has a center opening for reducing the overall weight of the SPG module (preferably frame-shaped connectors instead of plate connectors for reduced weight).

FIG. 27A illustrates an example cross-sectional view 2700A of a first example design layout for single SPS laminate along the short axis of the SPS laminate including a plurality of structural ribs built into the in-laminate frame, according to the present disclosure.

FIG. 27B illustrates an example plan view 2700B of the single SPS laminate of FIG. 27A including a plurality of structural ribs built into the in-laminate frame, according to the present disclosure.

FIG. 27C illustrates an example cross-sectional view 2700C of the single SPS laminate of FIG. 27A along the long axis of the SPS laminate, including a plurality of structural ribs, according to the present disclosure.

FIGS. 27A, 27B, and 27C illustrate views for the first design layout as explained with respect to FIG. 16. As shown using the structural ribs on long and short sides of the injection-molded frame structure increases the strength-to-weight ratio of the in-laminate frames for SPS units of FIG. 16. The example shows a single SPS using ribbed in-laminate frame).

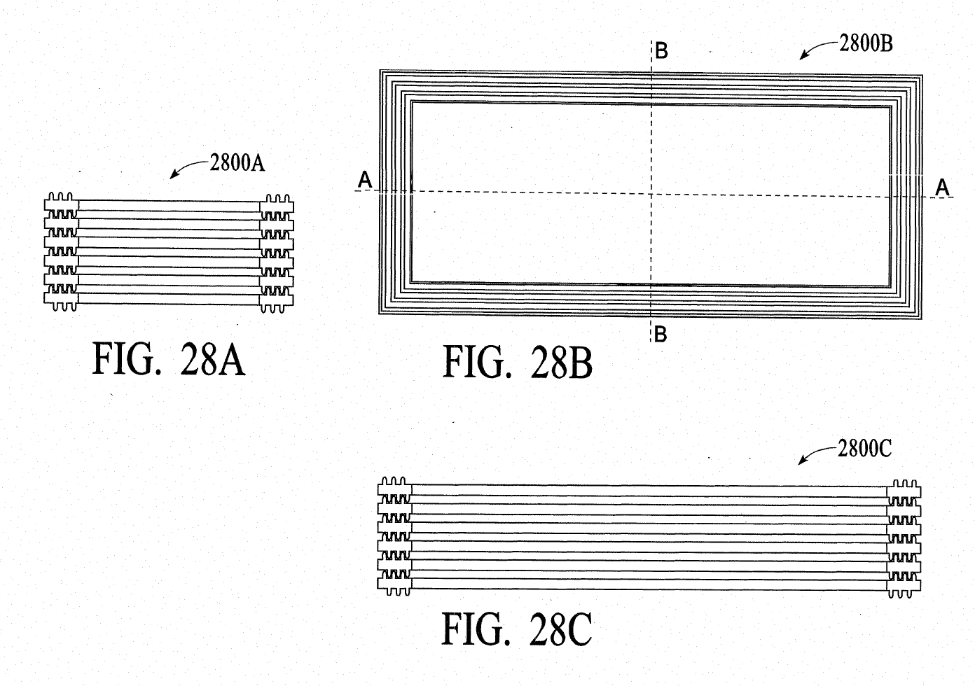

FIG. 28A illustrates an example cross-sectional view 2800A of a stack of plurality of SPS laminates of FIG. 27A along the short axis of the SPS laminates, each including a plurality of interleaved structural ribs built into the in-laminate frame, according to the present disclosure. As can be seen, there is an offset between the structural ribs on both the frame faces.

FIG. 28B illustrates an example plan view 2800B of a stack of plurality of SPS laminates of FIG. 27A, each including a plurality of interleaved structural ribs built into the in-laminate frame, according to the present disclosure. The structural ribs can be seen on either side (face) or one of the two sides (faces) or both (sides) faces of the frames.

FIG. 28C illustrates an example cross-sectional view 2800C of a stack of plurality of SPS laminates of FIG. 27 along the long axis of the SPS laminates, each including a plurality of interleaved structural ribs built into the in-laminate frame, according to the present disclosure. As can be seen, there is an offset between the structural ribs on both the frame faces. The example shown includes a total of six stacked frames. In other examples, there can be more stacked frames.

FIGS. 28A, 28B, and 28C illustrate views for the first design layout for as explained with respect to FIG. 16 for each SPS unit in the stack. As shown using the structural ribs on long and short sides of the injection-molded frame structure increases the strength-to-weight ratio of the in-laminate frames for SPS units as shown in FIG. 16. The example shows a stack of SPS using ribbed in-laminate frame).

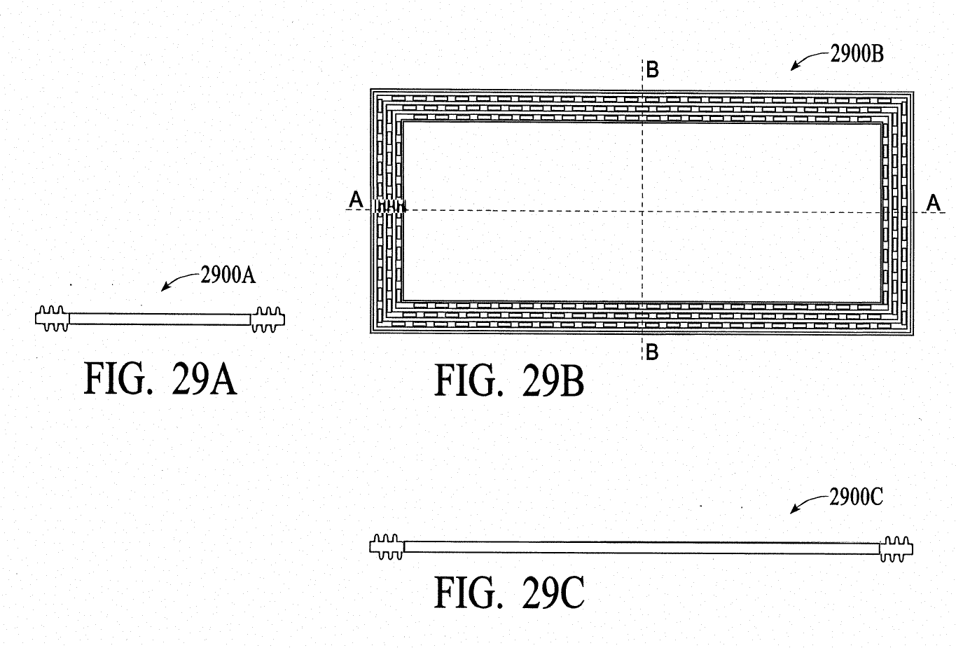

FIG. 29A illustrates an example cross-sectional view 2900A of a second example design layout for a single SPS laminate along the short axis of the SPS laminate, including a plurality of structural ribs and perforations built into the in-laminate frame, according to the present disclosure.

FIG. 29B illustrates an example plan view 2700B of the second example design layout for the single SPS laminate of FIG. 29A including a plurality of structural ribs and perforations built into the in-laminate frame, according to the present disclosure.

FIG. 29C illustrates an example cross-sectional view 2900C of the second example design layout for the single SPS laminate of FIG. 29A including a plurality of structural ribs and perforations built into the in-laminate frame, according to the present disclosure.

FIGS. 29A, 29B, and 29C illustrate views for the second design layout as explained with respect to FIG. 18. As shown using the structural ribs and perforations on long and short sides of the injection-molded frame structure increases the strength-to-weight ratio of the in-laminate frames for SPS units of FIG. 18. The example shows a single SPS using ribbed in-laminate frame).

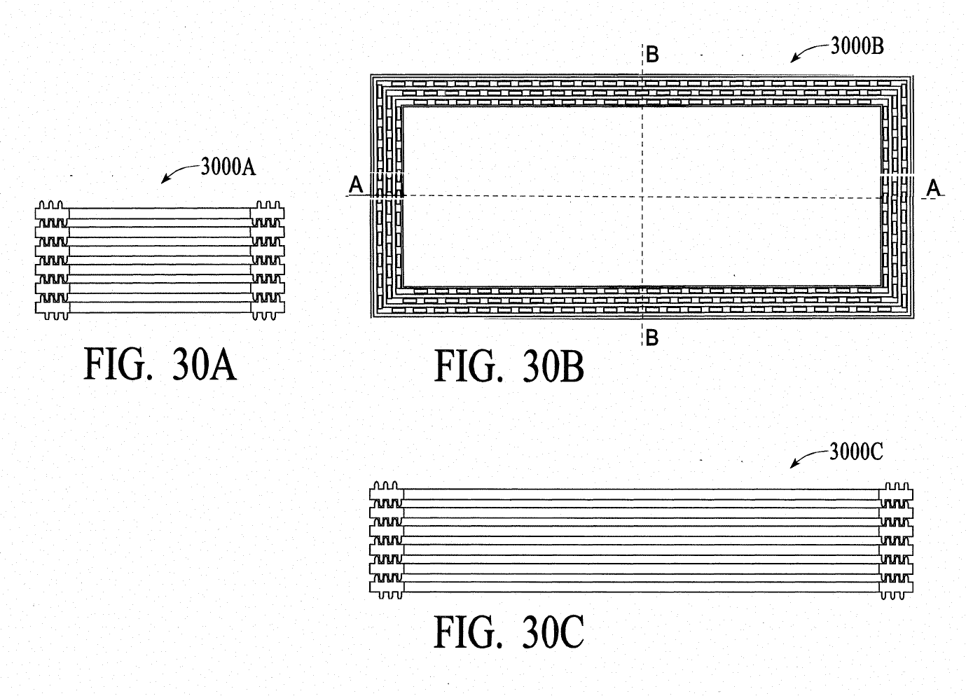

FIG. 30A illustrates an example cross-sectional view 3000A of a stack of plurality of SPS laminates of FIG. 29A each including a plurality of structural ribs and perforations, according to the present disclosure.

FIG. 30B illustrates an example plan view 3000B of a stack of plurality of SPS laminates of FIG. 29A, each including a plurality of structural ribs and perforations, according to the present disclosure.

FIG. 30C illustrates an example cross-sectional view 3000C of a stack of plurality of SPS laminates of FIG. 30 each including a plurality of structural ribs and perforations, according to the present disclosure.

FIGS. 30A, 30B, and 30C illustrate views for the second design layout as explained with respect to FIG. 18 for a stack of SPS units using perforated and in-laminate frames. As shown using the structural ribs and perforations on the short and long sides of the injection-molded frame structure increases the strength-to-weight ratio of the in-laminate frames for SPS units of FIG. 18. The example shows a stack of SPS units using ribbed, perforated, and in-laminate frames.

FIG. 31 illustrates an example 3100 of an open structure design of an SPG module 3102 design with a fixed-tilt vertical SPS units (collectively shown as 3102 3103) perpendicular to the large virtual planes of the module 3102, according to the present disclosure. As shown, the SPS units 3103 (SP1 SP2, SP3, SP4, SP5, SP6, SP7, SP8, SP9, and SP10) are perpendicular to the virtual planes of the SPG module 3102. The electromechanical or electro-structural connector plates (or parts) 3104 and 3110 (collectively shown) fold or hinge outward (or it may also hinge/fold inward) upon retraction. Also shown are hinging or pivoting axes 3106 and 3108. G is the spacing between adjacent SPS units and W is the width of a single SPS unit. In general, in a typical embodiment, G is approximately equal to greater than W (for instance, between W and 3W). The SPG module 3100 includes ten SPS units, however, the number of SPS units is typically between three and ten or can even be much larger (up to 100). Adjustable hinging or pivoting or folding end plates or open frame electromechanical or electro-structural connector may be made of thin rectangular frames for reduced weight and enhanced light capture through them.

FIG. 32 illustrates an another example 3200 of an open structure design of an SPG module 3202 design, with a fixed-tilt SPS units (collectively shown as 3202 3203) non-perpendicular or angled to the large virtual planes, according to the present disclosure. The connector plates (also referred to as adjustable hinging or pivoting end plates) 3204 and 3210 (collectively shown) fold or hinge outward (or may be inward too) upon retraction. In the example shown, all connector plates, also referred to as end plate or connector segments are folded outward upon retraction. Also shown are hinging or pivoting or folding axes 3206 and 3208. G is the spacing between adjacent SPS units and W is the width of a single SPS unit. In general, in a typical embodiment, G is approximately equal to greater than W (for instance, between W and 3W). The SPG module 3200 includes ten SPS units, however, the number of SPS units is typically between three and ten or can even be much larger (up to 100). Adjustable hinging or pivoting end plates or open frame electromechanical or electrochemical connectors (3204 and 3210) may be made of thin rectangular frames for reduced weight and enhanced light capture.

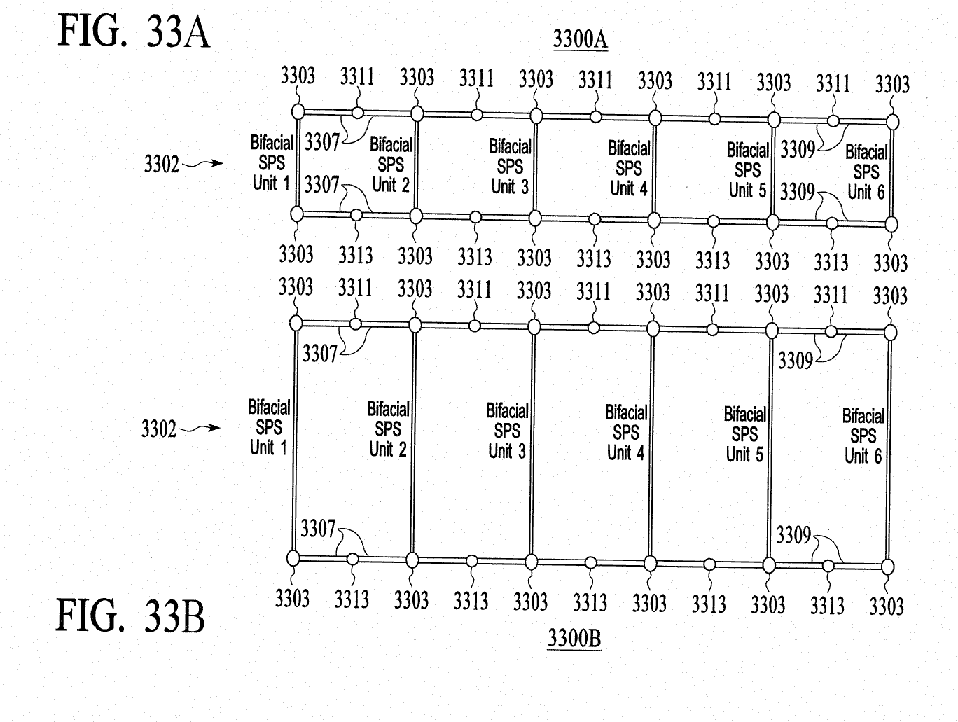

FIG. 33A illustrates an example side view 3300A and a top view 3300B of a design of an SPG module 3302 design, enabling manual SPS tilt adjustment (with respect to the larger virtual planes) for SPS units perpendicular to the large virtual planes, according to the present disclosure. This design provides fully open structure when the RDP-SPG module is fully extended, enabling full and efficient light capture from all directions. This design includes dual-axis electro-mechanical pivots (collectively shown as 3303) connected to the bifacial SPS units 1 through 6. The design further includes single-axis electro-mechanical pivots for each SPS unit. In one example, the dual-axis pivots can have a maximum rotation or leverage of 90 degrees, and the single-axis pivots can have a maximum rotation or leverage of 180 degrees. In the side view 3300A, the single-axis pivots in the top row are collectively referred to as 3311 and the single-axis pivots in the bottom row are collectively referred to as 3313. It can be appreciated by a person of ordinary skill in the art that in the top view 3300B, only the single-axis pivots in the top row (3311) are seen. Dual axis electromechanical pivots 3302, 3304 3303 and 3305 are connected to electromechanical or electro-structural building blocks the SPS units. In the side view 3300A, the dual-axis pivots in the top row are collectively referred to as 3303 and the dual-axis pivots in the bottom row are collectively referred to as 3305. It can be appreciated by a person of ordinary skill in the art that in the top view 3300B, only the dual-axis pivots in the top row (3302) are seen. As shown, pivoting rods or narrow rectangular electro-mechanical Connectors 3307 are connected to the SPS units. In one example, the connectors 3307 and 3309 are made up of composite polymer and have a thickness less than 0.100″). Four Pairs of Electro-Mechanical Connectors between Each Pair of Adjacent SPS Building Blocks (Two Pairs on Each End).

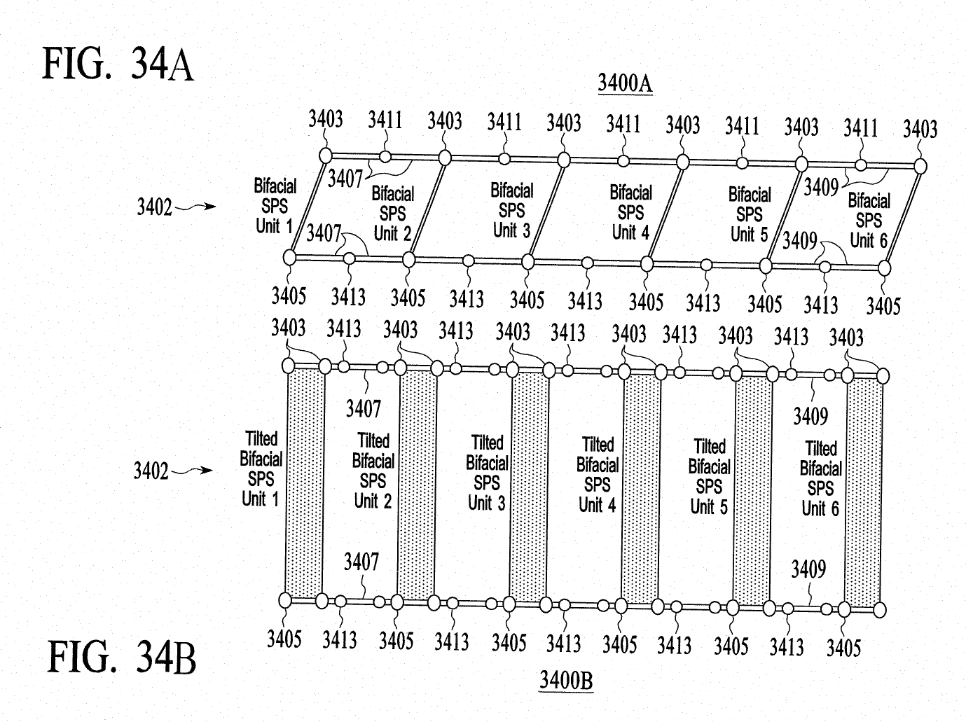

FIG. 34A illustrates an example side view 3400A and a top view 3400B of a design of an SPG module 3402 design, enabling manual SPS tilt adjustment for SPS units including setting the tilt to be non-perpendicular to the large virtual planes, according to the present disclosure. This design provides fully open structure when the RDP-SPG module is fully extended, enabling full light capture from all directions. This design includes dual-axis electro-mechanical pivots (collectively shown as 3403) connected to the bifacial SPS units 1 through 6. The design further includes single-axis electro-mechanical pivots for each SPS unit. In one example, the dual-axis pivots can have a maximum rotation or leverage of 90 degrees, and the single-axis pivots can have a maximum rotation or leverage of 180 degrees. In the side view 3400A, the single-axis pivots in the top row are collectively referred to as 3411 and the single-axis pivots in the bottom row are collectively referred to as 3413. It can be appreciated by a person of ordinary skill in the art that in the top view 3400B, only the single-axis pivots in the top row (3411) are seen. Dual axis electromechanical pivots 3402, 3404 3403 and 3405 are connected to electromechanical or electro-structural building blocks. In the side view 3400A, the dual-axis pivots in the top row are collectively referred to as 3403 and the dual-axis pivots in the bottom row are collectively referred to as 3405. It can be appreciated by a person of ordinary skill in the art that in the top view 3400B, only the dual-axis pivots in the top row (3403) are seen.

As shown, Pivoting Rods or Narrow Rectangular Electro-Mechanical Connectors 3307 are connected to the SPS units. In one example, the connectors 3307 and 3309 are made up of composite polymer and have a thickness less than 0.100″). Four Pairs of Electro-Mechanical Connectors between Each Pair of Adjacent SPS Building Blocks (Two Pairs on Each End). This design includes dual-axis (≤90°) electro-mechanical pivots (collectively shown as 3303) connected to the bifacial SPS units 1 through 6. The design further includes single-axis electro-mechanical pivots for each SPS unit.

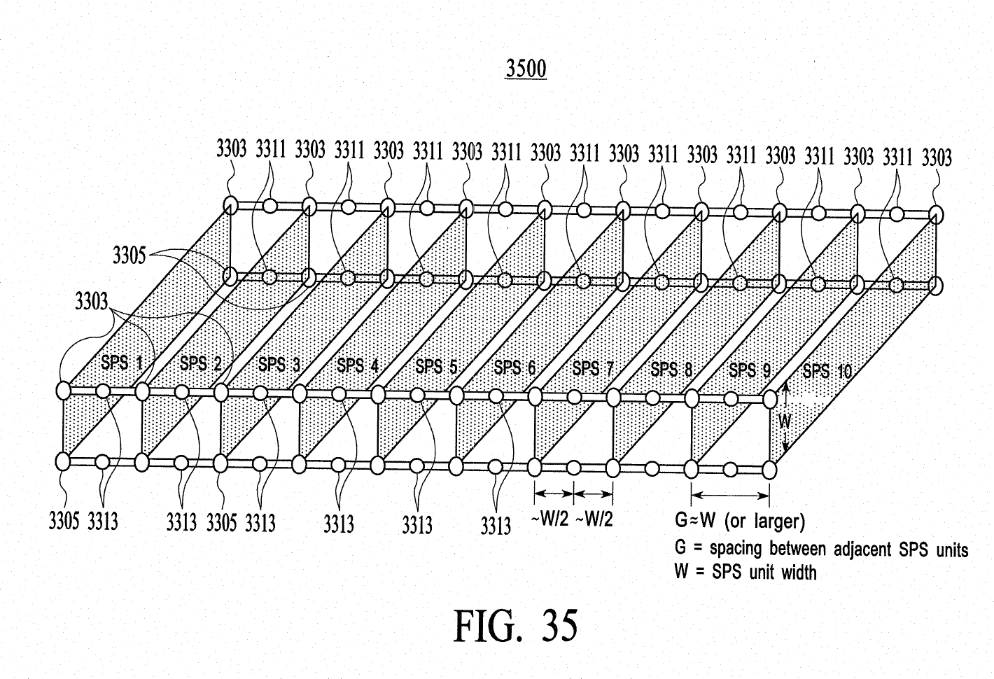

FIG. 35 illustrates a three-dimensional perspective of the representative example shown in the side view of FIG. 33A and top view of FIG. 33B, in accordance with the teachings of the present disclosure. The design shows the dual-Axis (≤90°) electro-mechanical pivots collectively referred to as 3303 and 3305, connected to the SPS units, and single axis (≤180°) electromechanical pivots, collectively referred to as 3311 and 3313. This design enables a manual (or automatic) SPS tilt adjustment. It also provides a fully open structure using pivoting rods or a narrow rectangular structure using the electro-mechanical connectors. Each open-structure RDP-SPG may be considered as a virtual or imaginary rectangular plane and comprises at least one group of the longer sides of the SPS units (SPS1 to SPS10). As can be seen, the SPS units are perpendicular to the large virtual plane.

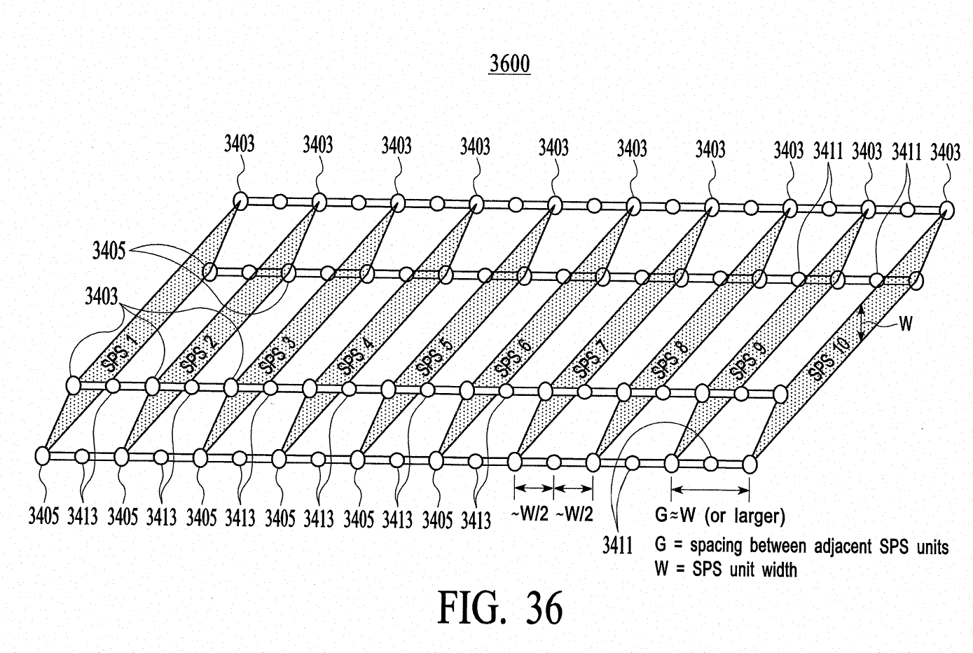

FIG. 36 illustrates a three-dimensional perspective of the representative example shown in the side view of FIG. 34A and top view of FIG. 34B, in accordance with the teachings of the present disclosure. The design shows the dual-Axis (≤90°) electro-mechanical pivots collectively referred to as 3403 and 3405, connected to the SPS units, and single axis (≤180°) electromechanical pivots, collectively referred to as 3411 and 3413. This design enables a manual (or automatic) SPS tilt adjustment. It also provides a fully open structure using pivoting rods or a narrow rectangular structure using the electro-mechanical connectors. Each open-structure RDP-SPG may be considered as a virtual or imaginary rectangular plane and comprises at least one group of the longer sides of the SPS units (SPS1 to SPS10). As can be seen, the SPS units are non-perpendicular to the large virtual plane.

FIG. 37 illustrates a first example 3700 of representative dimensions for an SPS building block comprising co-planar partitioned series-connected sub-cells (in this example, there are 12 sub-cells prepared by partitioning each full-size solar cell into 8×2=16 equal-area sub-cells and using 12 of such sub-cells made from 1.5 full-size cells), according to the present disclosure. This example, includes an in-laminate frame outer dimensions of 310.0 mm×107.0 mm. Z=1 (# of super-cells), S=0.75 (# of full bifacial cells), M=8×2 (cell partitioning) Super-cell scaling factors may be 12× voltage scale-up and 6x current scale-down. For a six SPS building block units (each SPS unit uses 0.75 laser-partitioned solar cells: 4.5 total)

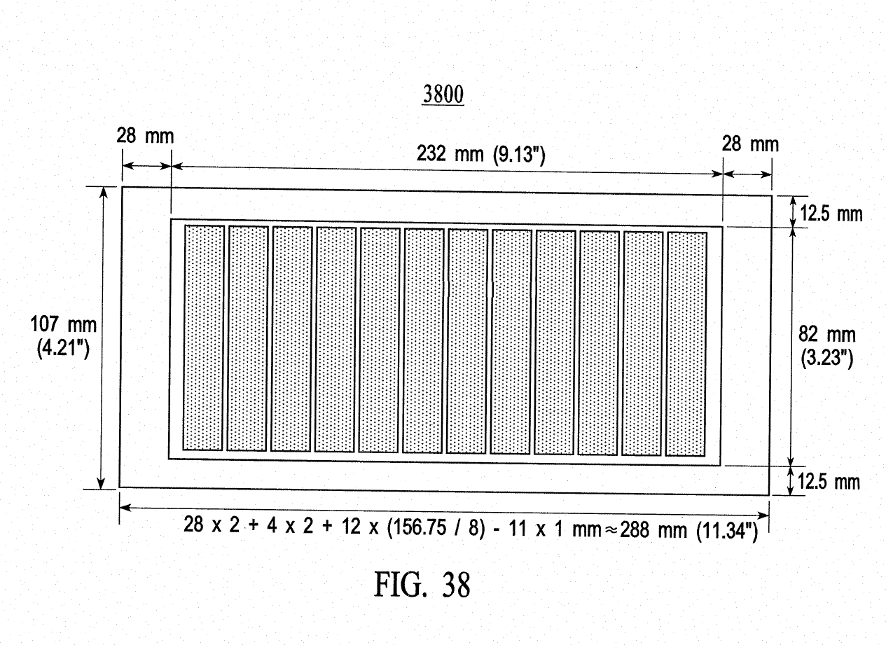

FIG. 38 illustrates a first example 3800 of representative dimensions for an SPS building block comprising overlapping partitioned series-connected sub-cells (in this example, there are 12 sub-cells prepared by partitioning each full-size solar cell into 8×2=16 equal-area sub-cells and using 12 of such sub-cells made from 1.5 full-size cells), according to the present disclosure. This example includes an in-laminate frame outer dimensions of 408.5 mm×193.0 mm with Z=1 (# of super-cells), S=2 (# of full bifacial cells), M=6×1 (cell partitioning) Super-cell scaling factors may be: 12× voltage scale-up and 6× current scale-down For a six SPS building block units (each SPS unit uses 2 laser-partitioned solar cells: 12 total)

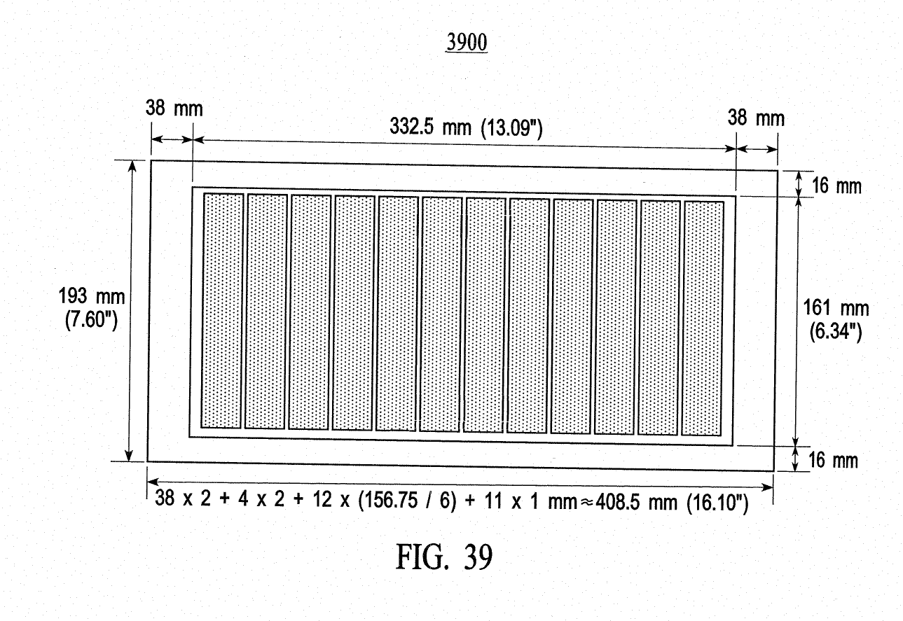

FIG. 39 illustrates a second example 3900 of representative dimensions for an SPS building block comprising co-planar partitioned series-connected sub-cells (in this example, there are 12 sub-cells prepared by partitioning each of 2 full-size solar cells into 6 equal-area sub-cells), according to the present. This example includes an in-laminate frame outer dimensions of 565.3 mm×193.0

Mm with Z=1 (# of super-cells), S=3 (# of full bifacial cells), M=4×1 (cell partitioning) Super-cell scaling factors may bel2x voltage scale-up and 4× current scale-down. For six SPS building block units (each SPS unit uses 3 laser-partitioned solar cells: 18 total).

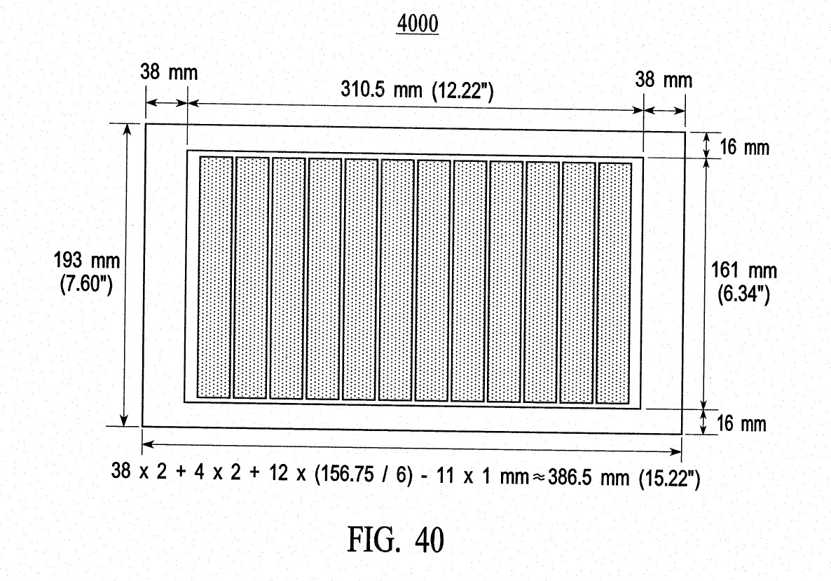

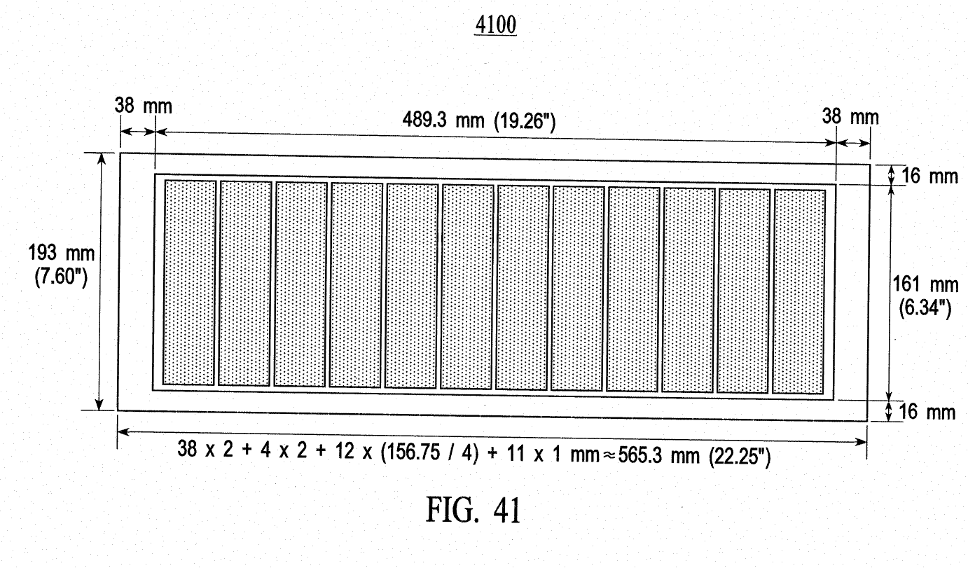

FIG. 40 illustrates a second example 4000 of representative dimensions for an SPS building block comprising overlapping partitioned series-connected sub-cells (in this example, there are 12 sub-cells prepared by partitioning each of 2 full-size solar cells into 6 equal-area sub-cells), according to the present disclosure. This example has an in-laminate frame outer dimensions of 722.0 mm×193.0 mm with Z=1 (# of super-cells), S=4 (# of full bifacial cells), M=3×1 (cell partitioning) Super-cell scaling factors may be 12× voltage scale-up and 3× current scale-down For a six SPS building block units (each SPS unit uses 4 laser-partitioned solar cells: 24 total) Each representative prototype RDP-SPG module (Designs I, II, III, IV) uses 6 SPS units 4×6 24 prototype SPS units using 58.5 bifacial mono-PERC or HIT (>21%) solar cells Laser-cut or CNC-cut in-Laminate Frames (made of black FR4 sheets)

FIG. 41 illustrates a third example 4100 of representative dimensions for an SPS building block comprising co-planar partitioned series-connected sub-cells (in this example, there are 12 sub-cells prepared by partitioning each of 3 full-size solar cells into 4 equal-area sub-cells), according to the present disclosure. In this example, FR4 Frames for SPS Building Block Units Use Z=1, C=1 (Full-Cell Width), S=3, M=4×1, Co-Planar Sub-Cells (3). Bifacial solar cell dimensions are assumed to be 156.75 mm×156.75 mm±0.25 mm and sub-cell to sub-cell spacing of 1 mm. Sub-cell edge spacings are assumed to be of 2 mm and 4 mm along the long and short sides of the SPS building block, respectively. MPPT board (with active bypass) dimensions may be approximately equal to 27 mm×18 mm. FR4 frame widths are assumed to be of 16 mm along the long sides and approximately equal to 38 mm along the short sides. Outer frame dimensions may be 565.3 mm×193 mm (22.25″×7.60″). Frame opening dimensions may be 489.3 mm×161 mm (19.26″×6.34″). The in-laminate frame-supported copper ribbon connectors and SPS leads are not shown

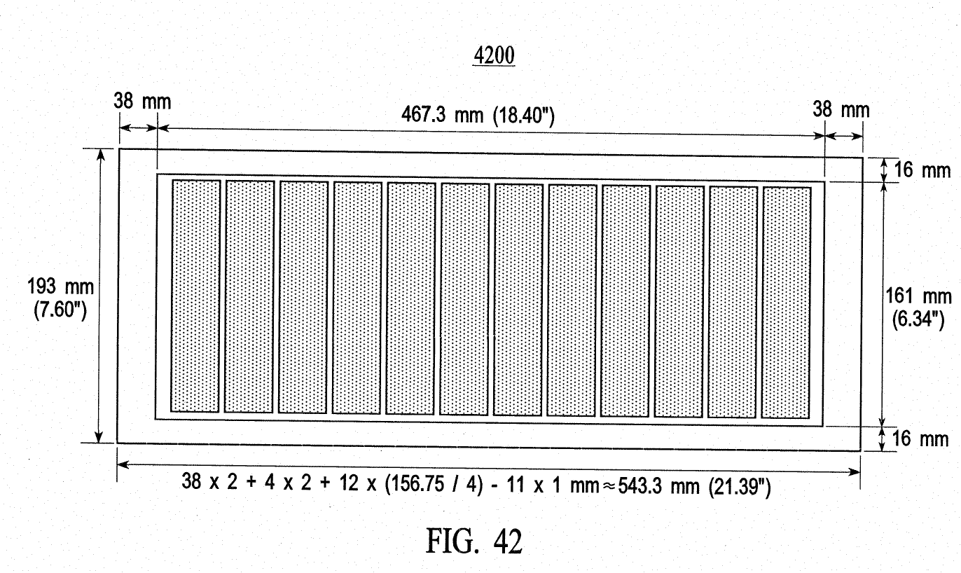

FIG. 42 illustrates a third example 4200 of representative dimensions for an SPS building block comprising overlapping partitioned series-connected sub-cells (in this example, there are 12 sub-cells prepared by partitioning each of 3 full-size solar cells into 4 equal-area sub-cells), according to the present disclosure. In this example, FR4 Frames for SPS Building Block Units may use Z=1, C=1 (Full-Cell Width), S=3, M=4×1, Overlapping Sub-Cells (3). Bifacial solar cell dimensions are assumed to be 156.75 mm×156.75 mm±0.25 mm and sub-cell to sub-cell spacing of 1 mm.

Sub-cell edge spacings are assumed to be 2 mm and 4 mm along the long and short sides of the SPS building block, respectively.

MPPT board (with active bypass) dimensions may be approximately equal to 27 mm×18 mm; various dimensions below are not shown to relative scale.

FR4 frame widths are assumed to be 16 mm along the long sides and approximately 38 mm along the short sides. Outer frame dimensions are assumed to be 543.3 mm×193 mm (21.39″×7.60″), frame opening dimensions may be 467.3 mm×161 mm (18.40″×6.34″).

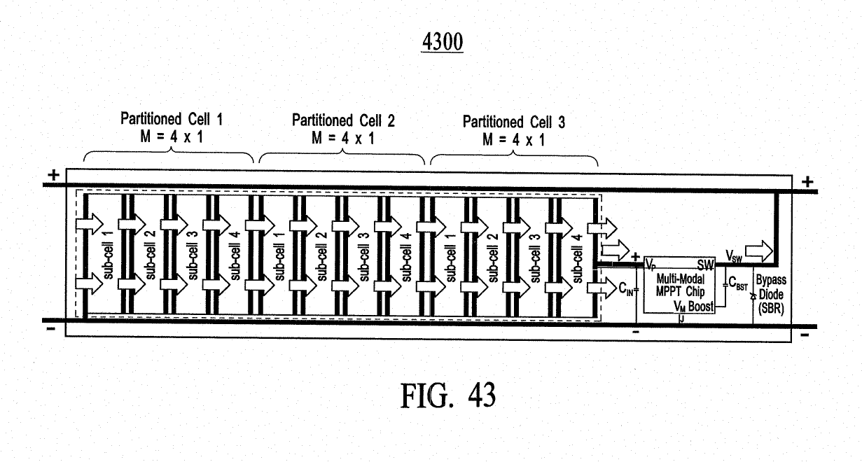

FIG. 43 illustrates an example 4300 of the schematic diagram of an SPS building block of FIG. 41 or FIG. 42, including the schematic electrical wiring diagram, comprising a single super cell, with said super-cell comprising 3×4=12 sub-cells, and a single multi-modal MPPT IC for distributed power maximization, according to the present disclosure. The design of FIG. 43 shows positive and negative leads on both ends of the SPS laminate. Illustrated in FIG. 43, is a Smart Power Slat (SPS) Building Block - SPS Shown comprising with a single 1 Super-Cell & 1 a single MPPT. An SPS unit (˜15 Wp), having Z=1 super-cell, C=1, 1 MPPT chip: N=S=3, M=4×1

The SPS unit has its positive & negative electrical leads both ends. There are 3×4=12 sub-cells in this SPS design (C=1 cell wide by 3 cells long, corresponding to 1 sub-cell wide by 12 sub-cells long with M=4×1 design). Rows of sub-cells connected in series are configured or coupled; using to use a single one MPPT chip for 12 pairs of series-connected sub-cells.

This design uses one MPPT chip for 12 series-connected sub-cells in 1 a single row of sub-cells. Because of this arrangement, the (current is scaled scaling down four times by 4× and the voltage is scaling scaled up by 12× twelve times.)

Relative dimensions are not shown to scale (for instance, the MPPT chip & support components, and partitioning gaps are much smaller than shown above).

Photo-generated PV electrical current flows in the direction of into the negative bus bars and out of the positive bus bars (from negative towards positive leads).

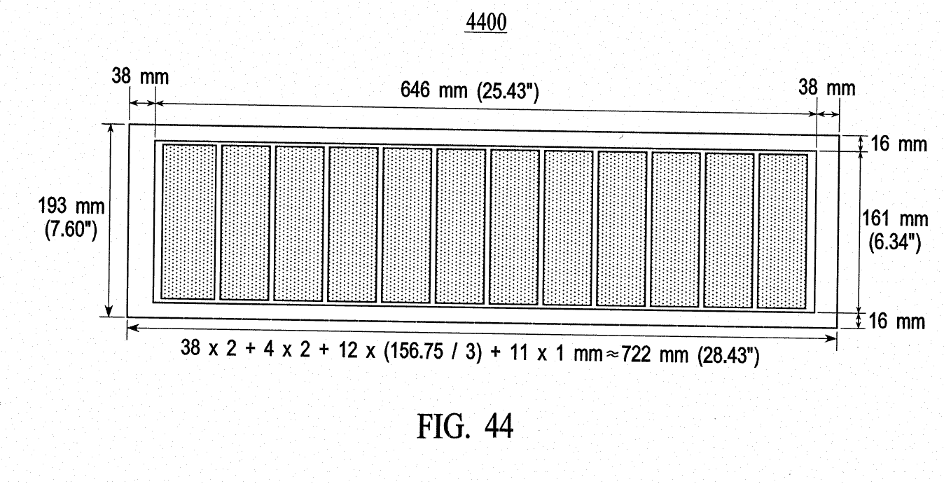

FIG. 44 illustrates a fourth example 4400 of representative dimensions for an SPS building block comprising co-planar partitioned series-connected sub-cells (in this example, there are 12 sub-cells prepared by partitioning each of 4 full-size solar cells into 3 equal-area sub-cells), according to the present disclosure. In this example, Composite Frames for SPS Building Block Units Using use Z=1, C=1 (Full-Cell Width), S=4, M=3×1, Co-Planar Sub-Cells. The assumed dimensions and spacings are as follows: Assume bifacial solar cell dimensions −156.75 mm×156.75 mm±0.25 mm and, sub-cell to sub-cell spacing of 1 mm, frame to sub-cell edge spacings of 2 mm and 4 mm along the long and short sides of the SPS building block, respectively.

The MPPT board (with active bypass) is assumed to have dimensions: ˜27 mm×18 mm; Assume the composite frame widths are assumed to be of 16 mm along the long sides and ˜38 mm along the short sides.

Outer frame dimensions: 722 mm×193 mm (28.43″×7.60″), frame opening dimensions: 646 mm×161 mm (25.43″×6.34″). The in-laminate frame-supported copper ribbon connectors and SPS leads are not shown.

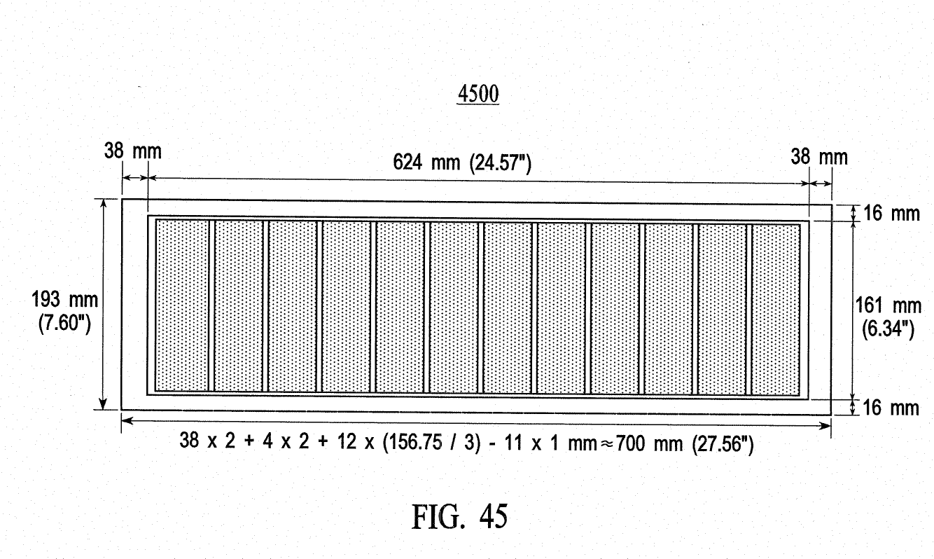

FIG. 45 illustrates a fourth example 4500 of representative dimensions for an SPS building block comprising overlapping partitioned series-connected sub-cells (in this example, there are 12 sub-cells prepared by partitioning each of 4 full-size solar cells into 3 equal-area sub-cells), according to the present disclosure. In this example, the dimensions may be as follows :

Composite frames for SPS Building Block Units Using Z=1, C=1 (Full-Cell Width), S=4, M=3×1, Overlapping Sub-Cells. Bifacial solar cell dimensions may be 156.75 mm×156.75 mm±0.25 mm and sub-cell to sub-cell spacing of 1 mm. Sub-cell edge spacings may be of 2 mm and 4 mm along the long and short sides of the SPS building block, respectively. MPPT board (with active bypass) dimensions may be approximately equal to 27 mm×18 mm. Composite frame widths may be 16 mm along the long sides and approximately 38 mm along the short sides. Outer frame dimensions may be 700 mm×193 mm (27.56″×7.60″), frame opening dimensions may be 624 mm×161 mm (24.57″×6.34″).

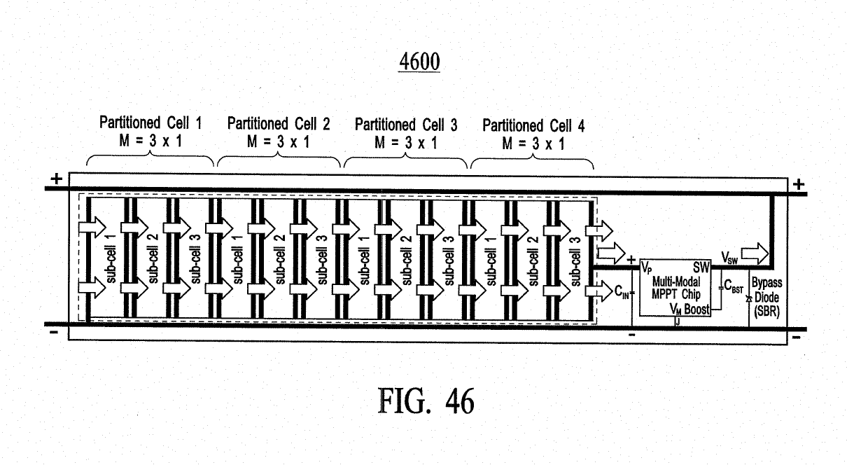

FIG. 46 illustrates an example 4600 of the schematic diagram of an SPS building block of FIG. 44 or FIG. 45, including the schematic electrical wiring diagram, comprising a single super cell, with said super-cell comprising 4×3=12 sub-cells, and a single multi-modal MPPT IC for distributed power maximization, according to the present disclosure. SPS is a bifacial, thin, elongated, planar, semi-rigid, lightweight laminate having at least one super-cell (number of super-cells in the SPS laminate is an integer Z≥1), and a plurality of N bifacial solar cells (wherein N=Z×S×C, and 2≤N≤20 depending on the SPS design needs), with each bifacial solar cell partitioned into M equal-area sub-cells (M=an integer between 2 and 16, preferably between 3 and 12). The bifacial SPS laminate is capable of receiving light on both faces and converting it to PV power. The SPS unit preferably has its positive & negative electrical leads on both ends. In this example, a rectangular SPS unit may have WP approximately equal to 20, having Z=1 super-cell, 1 MPPT chip: N=S=4, M=3×1. There may be 4×3=12 sub-cells in this SPS design (1-cell wide by 4 cells long, corresponding to 1 sub-cell wide by 12 sub-cells long with M=3×1 design). One row of sub-cells connected in series; using one MPPT chip for 12 series-connected sub-cells. In FIG. 46, relative dimensions are not shown to scale (for instance, the MPPT chip & support components, and partitioning gaps are much smaller than shown above). Photo-generated PV electrical current flows in the direction of into the negative bus bars and out of the positive bus bars (from negative towards positive leads).

Although the present disclosure has been particularly described with reference to embodiments thereof, it should be readily apparent to those of ordinary skill in the art that various changes, modifications and substitutes are intended within the form and details thereof, without departing from the spirit and scope of the disclosure.

Accordingly, it will be appreciated that in numerous instances some features of the disclosure will be employed without a corresponding use of other features. Further, those skilled in the art will understand that variations can be made in the number and arrangement of components illustrated in the above figures.

1. An apparatus coupled to receive the sunlight and generate photovoltaic electrical power comprising:
a vertically-deployable solar photovoltaic electricity generator constructed as a portable integrated assembly, operable in a photovoltaic electricity generation mode, storable in a volume compaction mode, and including:
a plurality of bifacial photovoltaic power generating slats with longer and shorter peripheral slat boundary sides
that connect together adjacent ones of the plurality of bifacial photovoltaic power generating slats,
with the longer boundary sides being substantially perpendicular to the direction of gravity in the volume compaction mode,
with the longer boundary sides being substantially perpendicular to the direction of gravity in the photovoltaic electricity generation mode,
with adjacent ones of the slats within the plurality of bifacial photovoltaic power generating slats being spaced apart by a finite gap allowing collection of the light on each of the bifacial photovoltaic power generating slats in the photovoltaic electricity generation mode, and
at least one power maximizing integrated circuit disposed on at least one of the plurality of bifacial photovoltaic power generating slats,
wherein the plurality of the bifacial photovoltaic power generating slats are coupled to deliver a photovoltaic generation power through the power maximizing integrated circuit, and
wherein the vertically-deployable solar photovoltaic electricity generator is set to the photovoltaic electricity generation mode when expanded and oriented along the force of gravity.

2. The apparatus according to claim 1, wherein
each of the plurality of bifacial photovoltaic power generating slats comprises a plurality of electrically connected solar cells with at least some of the plurality of solar cells connected in an electrical series, and wherein
the plurality of electrically connected solar cells are encapsulated in a lightweight laminate having bifacial light-receiving faces, with an optically transparent protective cover sheet over an encapsulant sheet covering each of the bifacial light-receiving faces.

3. The apparatus according to claim 1, wherein
each of the plurality of bifacial photovoltaic power generating slats comprises a plurality of bifacial crystalline silicon solar cells.

4. The apparatus according to claim 1, wherein the plurality of bifacial crystalline silicon solar cells are partitioned to scale down an electric current of each of the plurality of bifacial photovoltaic power generating slats by a current reduction scaling factor compared to the electric current of a non-partitioned bifacial crystalline silicon solar cell, and
wherein the partitioned bifacial crystalline silicon solar cells are coupled to convert light received on any one of the slat faces into electricity.

5. The apparatus according to claim 5, wherein the partitioned bifacial crystalline silicon solar cells are electrically connected together with at least some of the partitioned bifacial crystalline silicon solar cells being connected in electrical series, in a co-planar structure using copper electrical connectors.

6. The apparatus according to claim 7, wherein the partitioned bifacial crystalline silicon solar cells are electrically connected together with at least some of the partitioned bifacial crystalline silicon solar cells being connected in electrical series, in an edge-on-edge overlapping structure.

7. The apparatus according to claim 1, wherein at least one power maximizing integrated is circuit disposed on each one of the plurality of bifacial photovoltaic power generating slats.

8. The apparatus according to claim 1, wherein each of the plurality of bifacial photovoltaic power generating slats is a multi-layer laminate structure with two light-receiving sides.

9. The apparatus according to claim 1, wherein each of the plurality of bifacial photovoltaic power generating slats has
an in-laminate frame made of a fiber-reinforced polymeric composite material for structural and electrical interconnection support,
and a plurality of partitioned bifacial crystalline silicon solar cells fully nested within the in-laminate frame, and covered on at least one of the bifacial light-receiving sides with optically-transparent protective cover sheets over encapsulant sheets.

10. The apparatus according to claim 1, wherein the generator is coupled to provide its photovoltaic power as a DC electric power output to a storage battery or a DC consumption load or both.

11. The apparatus according to claim 1, wherein the generator is coupled to provide its photovoltaic power as an AC electric power output to an AC consumption load or to a storage battery as a DC power source or both.

12. The apparatus according to claim 1, wherein the plurality of bifacial photovoltaic power
generating slats are connected together using a plurality of electromechanical connectors attached to or near the shorter sides of the plurality of bifacial photovoltaic power generating slats, producing a retractable and expandable module structure, wherein
the electromechanical connectors have any one of folding, pivoting, and hinging structures to enable the volume compaction mode and the photovoltaic electricity generation mode.

13. The apparatus according to claim 2, wherein the longer peripheral slat
boundary sides of the plurality of bifacial photovoltaic power generating slats are parallel to each other producing an open parallel-spaced structure when expanded for the photoelectric electricity generation mode, and wherein
the plurality of bifacial photovoltaic power generating slats are closely stacked together with negligible spacing between adjacent bifacial photovoltaic power generating slats when retracted for the volume compaction mode.

14. The apparatus according claim 1, wherein the plurality of bifacial photovoltaic power generating slats have slat lengths along the longer peripheral slat boundary sides larger than slat widths along the shorter peripheral slat boundary sides, with both the slat lengths and slat widths being substantially larger than the thickness of each of the plurality of bifacial photovoltaic power generating slats.

15. The apparatus according to claim 1, wherein the power tracking integrated circuits is connected to at least one of the plurality of bifacial photovoltaic power generating slats to enhance the photovoltaic electricity generation power.

16. The apparatus according to claim 1, wherein the angles of the shorter peripheral slat boundary sides with respect to the gravity force direction is adjustable in a range chosen within 0 and 90 degrees.

17. A battery charger for an electric vehicle comprising the apparatus of claim 1.

18. A solar electricity generator comprising the apparatus according to claim 1, deployed in a greenhouse or on an agricultural farm or on a building window or an electric vehicle.

19. A solar electricity generator comprising the apparatus according to claim 1, attached to a street light pole or an electricity distribution pole or a transmission tower or a telecommunication pole or a telecommunication cell tower.

20. An apparatus coupled to receive the sunlight and generate photovoltaic electrical power comprising:
a solar photovoltaic electricity generator operable in a photovoltaic electricity generation mode, storable in a volume compaction mode and including:
a plurality of planar bifacial photovoltaic power generating slats with longer and shorter peripheral slat boundary sides and having bifacial light-receiving surfaces, and
at least one power maximizing integrated circuit disposed on at least one of the plurality of bifacial photovoltaic power generating slats,
wherein the plurality of the bifacial photovoltaic power generating slats are coupled to deliver a photovoltaic generation power through the power maximizing integrated circuit, and
wherein the plurality of planar bifacial photovoltaic power generating slats are retractable in the volume compaction mode when pushed together along a plurality of electromechanical connectors attached to or near the shorter peripheral slat boundary sides, and wherein
the plurality of planar bifacial photovoltaic power generating slats are expandable in the photovoltaic power generation mode when pulled apart from each other along the electromechanical connectors attached to or near the shorter peripheral slat boundary sides to expose the bifacial light-receiving surfaces.

21. The apparatus according to claim 20, wherein
each of the plurality of bifacial photovoltaic power generating slats comprises a multi-layer laminate structure having an in-laminate frame made of a fiber-reinforced polymeric composite material for structural and interconnection support as well as for electrical wirings and attachment of at least one of the plurality of power maximizing integrated circuits, and
a plurality of partitioned bifacial crystalline silicon solar cells nested within the in-laminate frame, and
covered on the bifacial light-receiving surfaces with optically-transparent protective cover sheets over encapsulant sheets.

22. The apparatus according to claim 20, wherein
at least one power maximizing integrated is circuit disposed on each one of the plurality of bifacial photovoltaic power generating slats.

23. An apparatus coupled to receive the sunlight and generate photovoltaic electrical power comprising:
a solar photovoltaic electricity generator operable in a photovoltaic electricity generation mode, storable in a volume compaction mode and including:
a plurality of bifacial photovoltaic power generating slats with longer and shorter peripheral slat boundary sides and having bifacial light-receiving surfaces,
at least one power maximizing integrated circuit disposed on at least one of the plurality of bifacial photovoltaic power generating slats,
wherein the plurality of the bifacial photovoltaic power generating slats are coupled to deliver a photovoltaic generation power through the power maximizing integrated circuit, and
wherein the plurality of bifacial photovoltaic power generating slats being retractable along a retraction axis in the volume compaction mode, and
expandable along an expansion axis in the photovoltaic electricity generation mode, and
a plurality of electromechanical connectors for structural and electrical connections of adjacent pairs of the plurality of bifacial photovoltaic power generating slats, wherein
each bifacial photovoltaic power generating slats further comprises a lightweight laminate having:
an in-laminate frame made of a composite fiber-reinforced-polymeric material,
a plurality of series-connected partitioned crystalline silicon solar cells nested within the in-laminate frame,
at least one of the plurality of power maximizing integrated circuits and electrical interconnection wiring attached to the in-laminate frame, and
optically-transparent cover sheets and encapsulant layers covering the bifacial light-receiving surfaces.

24. The apparatus according to claim 23, wherein
the in-laminate frames are injection-molded composite fiber-reinforced frames are ribbed or perforated for weight reduction.

25. The apparatus according to claim 23 wherein,
the electromechanical connectors are injection-molded composite fiber-reinforced polymeric connectors having electrical interconnection wiring attached to them.

26. The apparatus according to claim 23, wherein
the tilt angles of the planes of the plurality of bifacial photovoltaic power generating slats with respect to the retraction and expansion axis are adjustable in a range of 0 to 90 degrees.

27. The apparatus according to claim 23, wherein
at least one power maximizing integrated is circuit disposed on each one of the plurality of bifacial photovoltaic power generating slats.

28. The apparatus according to claim 1 or claim 20 or claim 23, wherein the apparatus that is moveable in accordance with a position of the sun, and
wherein the power maximizing integrated circuit is coupled to determine a placement position of the solar photovoltaic electricity generator based upon the detected position of the sun in the photovoltaic electricity generation mode.

29. The apparatus according to claim 7 or claim 22 or claim 27, wherein the apparatus that is moveable in accordance with a position of the sun, and
wherein the power maximizing integrated circuit is coupled to determine a placement position of the solar photovoltaic electricity generator based upon the detected position of the sun in the photovoltaic electricity generation mode.
